(19) United States
(12) Patent Application Publication
(10) Pub. No.: US 2018/0049281 A1
(43) Pub. Date: Feb. 15, 2018

(54) ORGANIC ELECTROLUMINESCENT ELEMENT

(71) Applicant: Konica Minolta, Inc., Tokyo (JP)

(72) Inventor: Shota HIROSAWA, Suginami-ku, Tokyo (JP)

(21) Appl. No.: 15/554,333

(22) PCT Filed: Mar. 3, 2016
(86) PCT No.: PCT/JP2016/056595

§ 371 Date: Aug. 29, 2017

(30) Foreign Application Priority Data
Mar. 11, 2015 (JP) 2015-048102

(51) Int. Cl. H05B 33/02; H05B 33/14; H01L 51/52

(52) U.S. Cl. CPC H05B 33/02; H01L 51/5246; H05B 33/145; B32B 2307/7242

(57) ABSTRACT

An organic electroluminescent element contains a flexible substrate having thereon: a first gas barrier layer; a second gas barrier layer laminated on the first gas barrier layer; a light emitting unit layer laminated on the second gas barrier layer; and a covering layer spreading over the light emitting unit layer. The first gas barrier layer is a polysilazane reforming layer. The second gas barrier layer is a layer incorporating a metal oxide containing a metal element selected from: vanadium (V), niobium (Nb), tantalum (Ta), titanium (Ti), zirconium (Zr), hafnium (Hf), magnesium (Mg), yttrium (Y), and aluminum (Al).

### TECHNOLOGICAL FIELD

The present invention relates to an organic electroluminescent element. More specifically, the present invention relates to an organic electroluminescent element having an excellent bending resistance property without peeling off the element during bending. The organic electroluminescent element has a high sealing property which enables to prevent generation of a non-light emitting portion (dark spots) when it is stored under high temperature and high humidity while achieving high bending resistance property.

### BACKGROUND

An organic electroluminescence element is a thin-type complete solid element utilizing electroluminescence produced by an organic material (hereafter, the term “electroluminescence” is also simply called as “EL”) and enabling to emit light at a voltage of approximately a few to a few tens volts. It has many excellent features of high luminance, high emission efficiency, thin-type, and lightweight. Therefore, an organic EL element has been applied for a surface-emitting body used for a backlight in various displays, a display panel of sign or emergency light, or an illuminating light source.

Particularly in recent years, an organic EL element using a resin substrate provided with a thin and lightweight gas barrier layer attracts attention. It has been used as a lighting source having an elaborate design using a curved surface.

However, when a bending momentum is applied to an organic EL element, a shear stress is produced between the layers constituting the organic EL element. It may induce peel off of the layer, and this is a problem. Therefore, it is required an organic EL element that will not induce peel off of the layers when the organic EL element is bent.

Even if an organic EL element does not induce peel off of the layers, there may be produced a problem of generating a non-light emitting portion caused by water penetrating thorough the edge portion of the organic EL element. This problem of generating a non-light emitting portion will remarkably occur under high temperature and high humidity.

For resolving these problems, there was proposed organic EL element provided with a sealing means in the past. For example, it was disclosed an organic EL element in which an inorganic thin film was adhered to a sealing member through an adhesive. The inorganic thin film spread over the light emitting laminate body (light emitting unit layer) on a gas barrier layer laminated on a substrate (for example, refer to Patent document 1).

However, the present inventors produced an organic EL element provided with the above-described sealing member by using a gas barrier layer formed with polysilazane, and evaluated the bending resistance property. It was found that the element component was peeled off

In addition, as a known gas barrier substrate, it was disclosed a gas barrier substrate having an improved close contact property between the gas barrier layer and a transparent conductive layer by installing an organic layer between the gas barrier layer and the transparent conductive layer (for example, refer to Patent document 2).

However, the present inventors produced an organic EL element installed with the above-described organic layer between the gas barrier layer formed with polysilazane and the light emitting unit layer, and evaluated the storage property of the organic EL element under bending state at high temperature and high humidity. It was found that a non-light emitting portion was generated in the organic EL element.

### PRIOR ART DOCUMENTS

### Patent Documents

Patent document 1: JP-A 2005-339863

Patent document 2: JP-A 2008-238541

### SUMMARY OF THE INVENTION

### Problems to be Solved by the Invention

The present invention has been made in view of the above-described problems and situation. An object of the present invention is to provide an organic EL element having an excellent sealing property. The organic EL element has an excellent bending resistance property without peeling off the element during bending, and it enables to prevent generation of a non-light emitting portion when it is stored under high temperature and high humidity such as 60° C. and 90% RH while achieving high bending resistance property.

### Means to Solve the Problems

The present inventors have made investigation into the reasons of the above-described problems in order to solve the problems. As a result, it was found the following. By installing a layer incorporating a predetermined metal oxide between a polysilazane layer and a light emitting unit layer, it is possible to provide an organic EL element without peeling off the element during bending, and enabling to prevent generation of a non-light emitting portion when the organic EL element is stored under high temperature and high humidity while achieving high bending resistance property. Thus, the present invention was achieved.

That is, the above-described problems of the present invention are solved by the following embodiments.
1. An organic electroluminescent element comprising: a first gas barrier layer laminated on a substrate; a second gas barrier layer laminated on the first gas barrier layer; a light emitting unit layer laminated on the second gas barrier layer; and a covering layer spreading over the light emitting unit layer,

wherein the first gas barrier layer is a polysilazane reforming layer; and

the second gas barrier layer is a layer incorporating a metal oxide containing a metal element selected from the group consisting of: vanadium (V), niobium (Nb), tantalum (Ta), titanium (Ti), zirconium (Zr), hafnium (Hf), magnesium (Mg), yttrium (Y), and aluminum (Al).
2. The organic electroluminescent element of the embodiment 1,

wherein a composition coefficient of an oxygen element contained in the metal oxide is smaller than a stoichiometric value.
3. The organic electroluminescent element of the embodiments 1 or 2,

wherein the metal oxide contains niobium (Nb).
4. The organic electroluminescent element of any one of the embodiments 1 to 3,

wherein the covering layer contains silicon (Si) and nitrogen (N).
5. The organic electroluminescent element of any one of the embodiments 1 to 4,

wherein a third gas barrier layer is provided between the substrate and the first gas barrier layer; and

the third gas barrier layer incorporates a silicon compound containing an element selected from the group consisting of: carbon (C), nitrogen (N), and oxygen (O).

### Effects of the Invention

By the above-described embodiments of the present invention, it is possible to provide an organic electroluminescent element having an excellent bending resistance property without peeling off the element during bending. The organic electroluminescent element has a high sealing property which enables to prevent generation of a non-light emitting portion when it is stored under high temperature and high humidity while achieving high bending resistance property.

Although it is not clearly understood, a formation mechanism and a mode of action of the effects of the present invention are presumed to be as follows.

Usually, when a covering layer is installed adjacent to a gas barrier layer (a first gas barrier layer) formed with polysilazane, it often occurs defection of close contact due to the surface morphology of the first gas barrier layer.

In the present invention, a layer containing the metal oxide (a second gas barrier layer) is placed between the covering layer and the first gas barrier layer. By this constitution, a close contact property of the first gas barrier layer with the covering layer is improved.

Namely, the second gas barrier layer functions as a binder between the first gas barrier layer and the covering layer. As a result, the element will not be peeled off during bending, and it is possible to provide an organic EL element having an excellent bending resistance property.

In addition, since the first gas barrier layer formed with polysilazane is a layer containing Si, an oxidation reaction of Si will proceed by reaction with water and oxygen under high temperature and high humidity conditions. Thereby, a gas barrier property of the layer will be deteriorated.

Consequently, it is presumed that an organic electroluminescent element of the present invention excels in sealing property to prevent generation of a non-light emitting portion when it is stored under high temperature and high humidity such as 60° C. and 90% RH while achieving high bending resistance property.

### BRIEF DESCRIPTION OF THE DRAWINGS

FIG. 1 is a schematic drawing which illustrates a schematic constitution of an organic electroluminescent element of a first embodiment of the present invention.

FIG. 2 is a schematic drawing which illustrates a schematic constitution of an organic electroluminescent element of a second embodiment of the present invention.

### EMBODIMENTS TO CARRY OUT THE INVENTION

An organic electroluminescent element of the present invention contains a substrate laminated thereon in the following sequential order: a first gas barrier layer; a second gas barrier layer; a light emitting unit layer; and a covering layer. It is characterized in that the first gas barrier layer is a polysilazane reforming layer, and the second gas barrier layer is a layer incorporating a predetermined metal oxide. These technical properties are common to the present inventions relating to claims 1 to 5.

A preferable embodiment of the present invention is that a composition coefficient of an oxygen element contained in the metal oxide is smaller than a stoichiometric value from the viewpoint of obtaining an effect of the present invention. By this it may effectively restrain an oxidation reaction of the element contained in the first gas barrier layer and the covering layer. Thereby it may be obtained an effect of reducing deterioration of the first gas barrier layer and the covering layer.

Another preferable embodiment of the present invention is that the metal oxide contains niobium (Nb) from the viewpoint of obtaining an effect of the present invention. Thereby it is possible to obtain effects of high storage stability, excellent emission efficiency, and uniform light emission.

Another preferable embodiment of the present invention is that the covering layer contains silicon (Si) and nitrogen (N) from the viewpoint of obtaining an effect of the present invention. When the covering layer contains Si, it may be restrain degradation of the covering layer caused by oxidation reaction. Thereby, it is possible to obtain a remarkable effect of the present invention.

Another preferable embodiment of the present invention is that the organic EL element contains a third gas barrier layer between the substrate and the first gas barrier layer, and that the third gas barrier layer incorporates a silicon compound containing an element selected from the group consisting of: carbon (C), nitrogen (N), and oxygen (O) from the viewpoint of obtaining an effect of the present invention. Thereby, it is possible to obtain a further improved sealing property. As a result, it is possible to obtain an effect of effectively reduced generation of a non-light emitting portion.

The present invention and the constitution elements thereof, as well as configurations and embodiments, will be detailed in the following. In the present description, when two figures are used to indicate a range of value before and after “to”, these figures are included in the range as a lowest limit value and an upper limit value.

### [Organic Electroluminescent Element]

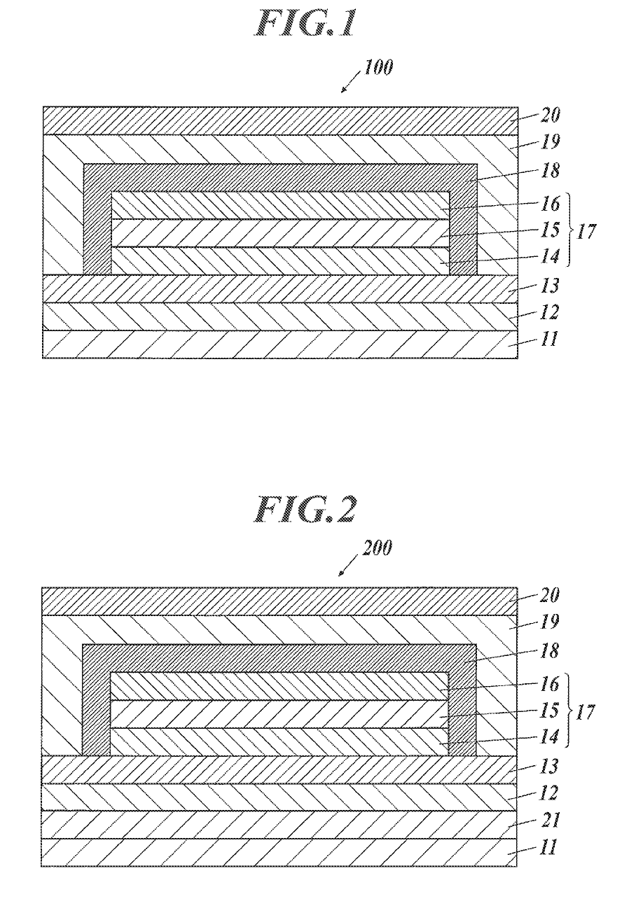

An organic electroluminescent element (organic EL element) 100 of the present invention contains: a first gas barrier layer 12 laminated on a flexible substrate 11 as a substrate; a second gas barrier layer 13 laminated on the first gas barrier layer 12; a light emitting unit layer 17 laminated on the second gas barrier layer 13; and a covering layer 18 spreading over the light emitting unit layer 17 (refer to FIG. 1). The organic EL element 100 is sealed by a sealing member 20 through a sealing adhesive layer 19 on the covering layer 18.

The organic EL element 100 of the present invention is characterized in that the first gas barrier layer 12 is a polysilazane reforming layer, and the second gas barrier layer 13 is a layer incorporating a metal oxide containing a metal element selected from the group consisting of: vanadium (V), niobium (Nb), tantalum (Ta), titanium (Ti), zirconium (Zr), hafnium (Hf), magnesium (Mg), yttrium (Y), and aluminum (Al).

Further, the organic EL element 100 has a so-called bottom-emission type constitution in which emission light from the light emitting unit layer 17 is extracted from the side of the flexible substrate 11.

The description will be given in the following order.
1. Organic electroluminescent element (First embodiment)
2. Organic electroluminescent element (Second embodiment)

### 1. Organic Electroluminescent Element (First Embodiment)

### [Flexible Substrate]

As a flexible substrate 11 used for an organic EL element 100, it is not specifically limited as long as it enables to provide an organic EL element 100 with a flexible property. As a flexible substrate, it may be cited a transparent resin film.

Examples of a resin for a resin film include: polyesters such as polyethylene terephthalate (PET) and polyethylene naphthalate (PEN), polyethylene, polypropylene, cellophane, cellulose esters and their derivatives such as cellulose diacetate, cellulose triacetate (TAC), cellulose acetate butyrate, cellulose acetate propionate (CAP), cellulose acetate phthalate, and cellulose nitrate, polyvinylidene chloride, polyvinyl alcohol, polyethylene vinyl alcohol, syndiotactic polystyrene, polycarbonate, norbornene resin, polymethyl pentene, polyether ketone, polyimide, polyether sulfone (PES), polyphenylene sulfide, polysulfones, polyether imide, polyether ketone imide, polyamide, fluororesin, Nylon, polymethyl methacrylate, acrylic resin, polyallylates and cycloolefin resins such as ARTON (trade name made by JSR Co. Ltd.) and APEL (trade name made by Mitsui Chemicals, Inc.).

Among these resin films, preferably used films are, for example, polyethylene terephthalate (PET), polybutylene terephthalate and polyethylene naphthalate (PEN) and polycarbonate (PC) with respect to the cost or the ease of acquisition.

Further, with respect to optical transparency, heat resistance and close adhesion with a first gas barrier layer 12, a heat resistant transparent film having a basic skeleton of silsesquioxane which contains an organic-inorganic hybrid structure may be preferably used.

The thickness of this flexible substrate 11 is preferably about 5 to 500 μm, and more preferably, it is within the range of 25 to 250 μm. It is preferable that the flexible substrate 11 has a light transparent property. It is possible to achieve an organic EL element 100 having light transparency when the flexible substrate 11 has a light transparent property.

### [First Gas Barrier Layer]

A first gas barrier layer 12 is provided between a flexible substrate 11 and a second gas barrier layer 13. In order to shield water and oxygen gas in the atmosphere which may penetrate in a light emitting unit layer 17 through the flexible substrate 11, the first gas barrier layer 12 is formed in such a manner to cover the flexible substrate 11 completely.

As a first gas barrier layer 12 as described above, it is preferable to use a polysilazane reforming layer which is formed by performing a reforming treatment to a polysilazane containing layer via irradiation with an active energy radiation

### (Polysilazane Reforming Layer)

A polysilazane reforming layer is preferably formed by: applying a coating solution containing polysilazane and drying; then, carrying out reforming treatment by irradiating the coated layer with an active energy radiation.

The polysilazane reforming layer forms a surface region in which reforming of polysilazane is more advanced, and there is formed a less reformed region or unreformed region at the lower portion of this region. In the present invention, “a polysilazane reforming layer” includes the less reformed region and unreformed region.

“Polysilazane” is a polymer having a silicon-nitrogen bond and it is a ceramic precursor inorganic polymer such as: SiO₂, Si₃N₄ and an intermediate solid solution of SiOₓN_{y} containing Si—N, Si—H and N—H bonds in the molecule. Specifically, preferable polysilazane has the following structure.

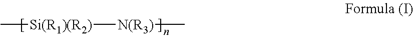

In the aforesaid Formula (I), R₁, R₂ and R₃ each independently represent a hydrogen atom, a substituted or unsubstituted alkyl group, aryl group, vinyl group or (trialkoxysilyl) alkyl group. R₁, R₂ and R₃ each may be the same or different with each other.

Here, as an alkyl group, there are cited a straight, branched or cyclic alkyl group with 1 to 8 carbon atoms. More specifically, examples of an alkyl group include: a methyl group, an ethyl group, an n-propyl group, an isopropyl group, an n-butyl group, an isobutyl group, a sec-butyl group, a tert-butyl group, an n-pentyl group, an isopentyl group, a neopentyl group, an n-hexyl group, an n-heptyl group, an n-octyl group, a 2-ethylhexyl group, a cyclopropyl group, a cyclopentyl group, and a cyclohexyl group.

As an aryl group, there are cited aryl groups having 6 to 30 carbon atoms. More specifically, there are cited: non-condensed hydrocarbon groups such as a phenyl group, a biphenyl group and a terphenyl group; condensed polycyclic hydrocarbon groups such as a pentalenyl group, an indenyl group, a naphthyl group, an azulenyl group, a heptalenyl group, a biphenylenyl group, a fluorenyl group, an acenaphthylenyl group, a pleiadenyl group, an acenaphthenyl group, a phenalenyl group, a phenanthryl group, an anthryl group, a fluoranthenyl group, an acephenanthrylenyl group, an aceanthrylenyl group, a triphenylenyl group, a pyrenyl group, a chrysenyl group and a naphthacenyl group.

As a (trialkoxysilyl)alkyl group, there are cited an alkyl group of 1 to 8 carbon atoms having a silyl group substituted with an alkoxyl group of 1 to 8 carbon atoms. More specifically, it may be cited: 3-(triethoxysilyl)propyl group and 3-(trimethoxysilyl)propyl group.

A substituent which may be present in the aforesaid R₁ to R₃ is not specifically limited. Examples thereof are: an alkyl group, a halogen atom, a hydroxyl group (—OH), a mercapto group (—SH), a cyano group (—CN), a sulfo group (—SO₃H), a carboxyl group (—COOH), and a nitro group (—NO₂).

In addition, a substituent which may be present will not be the same as R₁ to R₃ which are substituted. This means that, for example, when R₁ to R₃ each are an alkyl group, these are not further substituted with an alkyl group.

Among them, it is preferable that R₁, R₂ and R₃ each are: a hydrogen atom, a methyl group, an ethyl group, a propyl group, an isopropyl group, a butyl group, an isobutyl group, a tert-butyl group, a phenyl group, a vinyl group, a 3-(triethoxysilyl)propyl group, and 3-(trimethoxysilylpropyl)group.

In the aforesaid Formula (I), n is an integer, and it is preferable that n is determined so that polysilazane having a structure represented by Formula (I) will have a number average molecular weight of 150 to 150,000 g/mol. Among compounds having a structure represented by the aforesaid Formula (I), one of the preferable embodiments is “perhydropolysilazane” in which all of R₁, R₂ and R₃ are a hydrogen atom.

Polysilazane may have a structure represented by the following Formula (II).

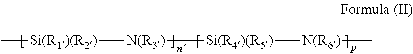

In the aforesaid Formula (II), R_{1′}, R_{2′}, R_{3′}, R_{4′}, R_{5′} and R_{6′} each independently represent a hydrogen atom, a substituted or unsubstituted alkyl group, aryl group, vinyl group or (trialkoxysilyl) alkyl group. R_{1′}, R_{2′}, R_{3′}, R_{4′}, R_{5′} and R_{6′} each may be the same or different with each other. The aforesaid substituted or unsubstituted alkyl group, aryl group, vinyl group or (trialkoxysilyl) alkyl group each have the same definition as described for the aforesaid Formula (I), therefore, the explanation to them is omitted.

In the aforesaid Formula (II), n′ and p each are an integer, and it is preferable that n′ and p are determined so that polysilazane having a structure represented by Formula (II) will have a number average molecular weight of 150 to 150,000 g/mol.

Further, n′ and p may be the same or different.

Among polysilazane compounds represented by Formula (II), the following are preferable: a compound in which R_{1′}, R_{3′}, and R_{6′} each represent a hydrogen atom, and R_{2′}, R_{4′}, and R_{5′} each represent a methyl group; a compound in which R_{1′}, R_{3′}, and R_{6′} each represent a hydrogen atom, R_{2′} and R_{4′} each represent a methyl group, and R_{5′} represents a vinyl group; and a compound in which R_{1′}, R_{3′}, R_{4′}, and R_{6′} each represent a hydrogen atom, and R_{2′} and R_{5′} each represent a methyl group.

Further, polysilazane may have a structure represented by the following Formula (III).

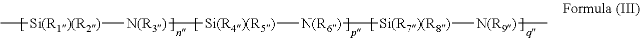

In the aforesaid Formula (III), R_{1″}, R_{2″}, R_{3″}, R_{4″}, R_{5″}, R_{6″}, R_{7″}, R_{8″}, and R_{9″} each independently represent a hydrogen atom, a substituted or unsubstituted alkyl group, aryl group, vinyl group or (trialkoxysilyl)alkyl group. R_{1″}, R_{2″}, R_{3″}, R_{4″}, R_{5″}, R_{6″}, R_{7″}, R_{8″}, and R_{9″} each may be the same or different with each other. The aforesaid substituted or unsubstituted alkyl group, aryl group, vinyl group or (trialkoxysilyl)alkyl group each have the same definition as described for the aforesaid Formula (I), therefore, the explanation to them is omitted.

In the aforesaid Formula (III), n″, p″ and q each are an integer, and it is preferable that n″, p″ and q are determined so that polysilazane having a structure represented by Formula (III) will have a number average molecular weight of 150 to 150,000 g/mol.

Further, n″, p″ and q may be the same or different.

Among polysilazane compounds represented by Formula (III), a preferable is a compound in which R_{1″}, R_{3″}, and R_{6″} each represent a hydrogen atom, R_{2″}, R_{4″}, R_{5″} and R_{8″} each represent a methyl group, R_{9″} represents a (trialkoxysilyl)alkyl group, and R_{7″} represents an alkyl group or a hydrogen atom.

On the other hand, an organopolysilazane, which has a structure of substituting a part of hydrogen atoms bonded to Si with an alkyl group, will improve adhesiveness with the underlying substrate by having an alkyl group such as a methyl group. And it is possible to give tenacity to a ceramic film made of stiff and breakable polysilazane. It has a merit of decreased generation of crack even when the (average) film thickness is increased. According to an application, one of these perhydropolysilazane and organopolysilazane may be selected and they may be used in combination.

Perhydropolysilazane is presumed to have a ring structure containing a straight chain, and a ring structure mainly composed of a 6- and an 8-membered ring. Its molecular weight is about 600 to 2,000 (in polystyrene conversion value) in a number average molecular weight (Mn). It has a material of liquid and solid, and the state depends on the molecular weight.

Polysilazane is commercially available in a solution state dissolved in an organic solvent. A commercially available product may be used directly as a coating liquid for producing a polysilazane reforming layer.

Examples of commercially available polysilazane are: AQUAMICA™ NN120-10, NN120-20, NAX120-20, NN110, NN310, NN320, NL110A, NL120A, NL120-20, NL150A, NP110, NP140, and SP140, which are supplied by AZ Electronic Materials, Ltd.

Although another examples of usable polysilazane are not specifically limited, examples of polysilazane which may be converted to ceramic at a low temperature are: silyl alkoxide added polysilazane, being produced by reacting silyl alkoxide with the above-described polysilazane (for example, refer to JP-A 5-238827); glycidol added polysilazane, being produced by reacting glycidol (for example, refer to JP-A 6-122852); alcohol added polysilazane, being produced by reacting alcohol (for example, refer to JP-A 6-240208); metal carboxylic acid salt added polysilazane, being produced by reacting metal carboxylate (for example, refer to JP-A 6-299118); acetyl acetonate complex added polysilazane, being produced by reacting acetyl acetonate complex containing a metal (for example, refer to JP-A 6-306329); and metal fine particle added polysilazane, being produced by adding metal fine particles (for example, refer to JP-A 7-196986).

When polysilazane is used, the content of polysilazane in the polysilazane layer before subjecting to a reforming treatment may be made to be 100 mass %, in which the total mass of the polysilazane reforming layer is set to be 100 mass %.

Further, when a polysilazane reforming layer contains other compound than polysilazane, it is preferable that the content of polysilazane in the layer is in the range of 10 to 99 mass %, more preferably, it is in the range of 40 to 95 mass %, and still more preferably, it is in the range of 70 to 95 mass %.

A forming method of a polysilazane reforming layer by a coating method is not specifically limited, and known methods may be adopted. It is preferable that a coating solution containing polysilazane with a catalyst when required in an organic solvent for forming a polysilazane reforming layer is applied with a known wet coating method, and a reforming treatment is performed after removing the solvent with evaporation.

### (Coating Solution for Forming a Polysilazane Reforming Layer)

As a solvent to prepare a coating solution for forming a polysilazane reforming layer, it is not specifically limited as long as it will dissolve polysilazane.

Preferable are solvents without containing water or a reactive group (for example, a hydroxyl group, or an amino group), which easily react with polysilazane. It is preferable to use an unreactive organic solvent. In particular, aprotic organic solvent is more preferable.

Specific examples of an aprotic solvent are as follows: an aliphatic hydrocarbon, an alicyclic hydrocarbon and an aromatic hydrocarbon such as pentane, hexane, cyclohexane, toluene, xylene, Solvesso™, and turpentine; a halogenated hydrocarbon solvent such as methylene chloride and trichloroethane; an ester such as ethyl acetate and butyl acetate; a ketone such as acetone and methyl ethyl ketone; an aliphatic ether such as dibutyl ether; an alicyclic ether such as dioxane and tetrahydrofuran; and alkylene glycol dialkyl ether and polyalkylene glycol dialkyl ethers (such as diglyme).

These organic solvents may be chosen in accordance with characteristics, such as solubility of silicon compound, and an evaporation rate of a solvent, and a plurality of solvents may be mixed.

A concentration of polysilazane in a coating solution for forming a polysilazane reforming layer is not specifically limited. Although it depends on a layer thickness and a pot life, it is preferably in the range of 1 to 80 mass %, more preferably, it is in the range of 5 to 50 mass %, and still more preferably, it is in the range of 10 to 40 mass %.

A coating solution for forming a polysilazane reforming layer preferably contains a catalyst in order to accelerate reforming.

Examples of a catalyst include: amine compounds such as N,N-diethylethanolamine, N,N-dimethylethanolamine, triethanolamine, triethylamine, 3-morpholino-propylamine, N,N,N′,N′-tetramethyl-1,3-diaminopropane, and N,N,N′,N′-tetramethyl-1,6-diaminohexane; metal complexes of a Pt compound such as Pt acetyl acetonate, a Pd compound such as Pd propionate, and a Rh compound such as Rh acetyl acetonate; N-heterocyclic compounds of pyridine derivatives such as pyridine, α-picoline, β-picoline, γ-picoline, piperidine, lutidine, pyrimidine, and pyridazine; DBU (1,8- diazabicyclo[5.4.0]-7-undecene), DBN (1,5- diazabicyclo[4.3.0]-5-nonene); organic acids such as acetic acid, propionic acid, butyric acid, valeric acid, maleic acid, stearic acid; inorganic acids such as hydrochloric acid, nitric acid, sulfuric acid, and hydrogen peroxide. Among them, it is preferable to use an amine compound.

As a concentration of a catalyst added, it is preferably in the range of 0.1 to 10 mass %, more preferably, it is in the range of 0.5 to 7 mass % based on the mass of polysilazane.

By making the concentration of a catalyst in this range, it is possible to avoid excessive formation of silanol due to a rapid advance in reaction, decrease of a layer density and increase of layer defects.

A coating solution for forming a polysilazane reforming layer may contain an additive as described below when needed.

Examples thereof are: cellulose ethers, cellulose esters such as ethyl cellulose, nitro cellulose, cellulose acetate, and cellulose acetobutylate; natural resins such as rubber and a rosin resin; synthetic resins such as a polymerized resin; condensed resins such as aminoplast, specifically a urea resin, a melamine-formaldehyde resin, an alkyd resin, an acrylic resin, a polyester or a modified polyester, epoxide, polyisocyanate or blocked polyisocyanate, and polysiloxane.

### (Method for Applying a Coating Solution for Forming a Polysilazane Reforming Layer)

A conventionally known appropriate wet coating method, may be adopted as a coating method of a coating solution for forming a polysilazane reforming layer. Specific examples of a coating method include: a spin coat method, a roll coat method, a flow coat method, an inkjet method, a spray coat method, a printing method, a dip coat method, a casting film forming method, a bar coat method and a gravure printing method.

A coating thickness may be appropriately set up according to the purpose. For example, a coating thickness per one polysilazane reforming layer may be set up so that the thickness after being dried is preferably about 10 nm to 10 μm, more preferably, it is in the range of 15 nm to 1 μm, still more preferably, it is in the range of 20 to 500 nm.

When the thickness is 10 nm or more, a sufficient gas barrier property will be obtained, and when the thickness is 10 μm or less, stable coating will be achieved during layer formation and high light transparency will be realized.

After applying the coating solution, it is preferable that the coated layer is dried. An organic solvent contained in the coating solution will be removed by drying the coated layer. Here, the organic solvent contained in the coating solution may be removed completely, or the organic solvent may be remained partially.

A suitable polysilazane reforming layer may be formed even when the organic solvent remains partially. When it remains in the layer, it will be removed later.

Although a drying temperature of the coated layer depends on the substrate used, it is preferable in the range of 50 to 200° C. For example, when a polyethylene terephthalate substrate having a glass transposition temperature (Tg) of 70° C. is used, it is preferable to set a drying temperature to 150° C. or less by considering heat deformation of the substrate.

The above-described temperature may be set up by using a hot plate, an oven or a furnace. It is preferable that the drying time is set up to be a short time. For example, when the drying temperature is 150° C., it is preferable that the drying time is set up to be 30 minutes or less. Further, a drying atmosphere may be any one of the conditions of under air, under nitrogen, under argon, under vacuum and under controlled reduced oxygen density.

A method for a coated layer obtained by applying a coating solution for forming a polysilazane reforming layer may contain a step of removing water before performing a reforming treatment or during a reforming treatment. As a step of removing water, it is preferable to dehumidify with keeping a low humidity condition. The humidity under a low humidity condition will change depending on a temperature. The preferable embodiment is indicated by fixing a dew point containing a relation of temperature and humidity.

A preferable dew point is 4° C. or less (temperature of 25° C. and humidity of 25%). A more preferable dew point is −5° C. or less (temperature of 25° C. and humidity of 10%), and preferably, the keeping time is suitably determined on the thickness of the polysilazane reforming layer.

When the thickness of the polysilazane reforming layer is 1.0 μm or less, a preferable dew point is −5° C. or less and a preferable keeping time is 1 minute or less.

In addition, although a lowest limit of a dew point is not specifically limited, usually, it is −50° C. or more, and preferably, it is −40° C. or more.

Removing water before performing a reforming treatment or during a reforming treatment is a preferable embodiment from the viewpoint of accelerating dehydration reaction of a polysilazane reforming layer which has been converted to silanol.

### (Reforming Treatment of a Polysilazane Coated Layer Formed by a Coating Method)

A reforming treatment of a polysilazane coated layer formed by a coating method indicates a conversion reaction of polysilazane into silicon oxide or silicon oxynitride. More specifically, it is a treatment in which a polysilazane coated later is reformed into an inorganic layer which exhibits a gas barrier property.

The conversion reaction of polysilazane into silicon oxide or silicon oxynitride may be done by a suitably adopted known method.

As a reforming treatment, preferable are conversion reactions of a plasma treatment and a UV ray irradiation treatment enabling to achieve a conversion reaction at a relatively low temperature from the viewpoint of application to a resin film substrate.

### (Plasma Treatment)

Although a known plasma method may be used for a reforming treatment, preferably it is cited an atmospheric pressure plasma treatment.

An atmospheric pressure plasma CVD method, which performs a plasma CVD process near the atmospheric pressure, does not require a reduced pressure in contrast with a vacuum plasma CVD method. Not only its production efficiency is high, but its film forming speed is high since a plasma density is high. Further, compared with a condition of a conventional CVD method, since an average free path of a gas is very short under a high-pressure of an atmospheric pressure, it may be obtained an extremely homogeneous film.

When an atmospheric pressure plasma treatment is carried out, it is used a nitrogen gas or elements of group 18 in the periodic table as a discharge gas. Specifically, it is used: helium, neon, argon, krypton, xenon or radon. Of these, nitrogen, helium and argon are preferably used, and, specifically, nitrogen is most preferably used in view of the low cost.

### (UV Ray Irradiation Treatment)

A treatment by irradiation with UV rays is preferable as a reforming treatment. Ozone and active oxygen, which are produced by UV rays (the same meaning as UV light), have high oxidation ability. Therefore, it is possible to form silicon oxide or silicon oxynitride, each having a high density and high insulating ability, at a low temperature.

By this UV ray irradiation, the substrate will be heated, O₂ and H₂O, a UV absorbing agent and polysilazane itself, which contribute to convert to ceramic (silica conversion), will be exited and activated. As a result, polysilazane becomes exited, and conversion of polysilazane into ceramics will be promoted. Moreover, an obtained polysilazane reforming layer will become denser.

The UV ray irradiation may be done at any moment after formation of a coated layer.

For a UV ray irradiation treatment, it may be used any conventionally used UV ray generating apparatus. In general, although a UV ray is an electromagnetic wave having a wavelength of 10 to 400 nm, it is preferable that a UV ray having 210 to 375 nm is used as a UV ray irradiation treatment except for a vacuum UV ray (10 to 200 nm) treatment.

When irradiating with UV rays, it is preferable that irradiation strength and irradiating time are set up within the range in which the substrate supporting a polysilazane layer to be reformed does not get damage.

When a plastic film is used as a substrate, an example of an irradiation treatment is as follows: using a lamp of 2 kW (80 W/cm×25 cm); adjusting the distance between the substrate and the UV irradiation lamp so that the strength at the substrate surface becomes to be 20 to 300 mW/cm², preferably to be 50 to 200 mW/cm²; and irradiation is done for 0.1 second to 10 minutes.

In general, in the case of a plastic film, when the temperature of a substrate is less than 150° C. during the UV irradiation treatment, a property of the substrate will not be damaged to result in deformation of the substrate or deterioration of its strength.

However, in the case of a highly thermal resistive film such as polyimide, it is possible to carry out a reforming treatment at a higher temperature. Consequently, as a temperature of a substrate during a UV ray irradiation treatment, there is no general upper limit. It may be suitably set up by one skilled in the art according to the kind of substrate.

The environment of the UV irradiation is not limited in particular. It may be done in the air.

Examples of an apparatus to generate UV rays include: a metal halide lamp, a high pressure mercury lamp, a low pressure mercury lamp, a xenon arc lamp, a carbon arc lamp, an excimer lamp (a single wavelength of 172 nm, 222 nm, or 308 nm, for example, manufactured by Ushio Inc., M. D. COM. Inc.), and a UV light laser. However, the present invention is not limited to them.

When the generated UV rays are irradiated to a polysilazane reforming layer, it is preferable that irradiation of the generated UV rays to the polysilazane reforming layer is done after making reflex with a reflex plate from the viewpoint of achieving improved efficiency and uniform irradiation.

The UV ray irradiation may be applicable to a batch treatment and a continuous treatment. It may be suitably selected according to a shape of a substrate used. For example, in the case of a batch treatment, a laminated body having a polysilazane reforming layer on the surface thereof may be treated in a UV ray furnace which is provided with a UV ray generating source. A UV ray furnace itself is generally known, and it may be used a UV ray furnace made by Eye Graphics Co. Ltd.

Further, when a laminated body having a polysilazane reforming layer on the surface thereof is an elongated film, making ceramic will be done by continuously irradiating with UV rays in a drying zone provided with the aforesaid UV ray generating source while conveying this elongated film.

The time required for UV ray irradiation depends on the used substrate, the composition and the density of the polysilazane reforming layer. It is generally, 0.1 second to 10 minutes, and preferably, it is 0.5 seconds to 3 minutes.

### (Vacuum UV Ray Irradiation Treatment: Excimer Irradiation Treatment)

To a polysilazane reforming layer, one of the most preferable reforming treatments is a treatment by irradiation with vacuum UV rays (excimer irradiation treatment).

A treatment by irradiation with vacuum UV rays uses a light energy of wavelength of 100 to 200 nm, preferably, a light energy of wavelength of 100 to 180 nm. This energy is larger than an atomic binding force in a polysilazane compound. By using this light energy, it is possible to make proceed with an oxidation reaction with active oxygen or ozone while directly breaking an atomic bond only with an effect of a photon, which is called as a photo quantum process. As a result, formation of silicon oxide layer will be achieved at a relatively low temperature (about 200° C. or less).

In addition, when carrying out an excimer irradiation treatment, it is preferable to use a thermal treatment in combination as described above. The detailed thermal conditions are as described above.

The radiation source is only required to emit a light having a wavelength of 100 to 180 nm. Suitable light sources are: an excimer radiator (for example, Xe excimer lamp) having a maximum radiation at 172 nm; a low pressure mercury lamp having a bright line at 185 nm; a medium pressure and a high pressure mercury lamp having a component of a wavelength of 230 nm or less; and an excimer lamp having a maximum radiation at 222 nm.

Among them, since a Xe excimer lamp emits ultraviolet rays of a single short wavelength of 172 nm, it is excellent in luminous efficiency. Oxygen has a large absorption coefficient to this light, as a result, it enables to generate a radical oxygen atom species and ozone in high concentration with a very small amount of oxygen.

Moreover, it is known that the light energy of a short wavelength of 172 nm has a high potential to dissociate a bond in an organic substance. Property modification of a polysilazane film will be realized in a short time with the high energy which is possessed by this active oxygen, ozone, and UV ray radiation.

An excimer lamp has a high efficiency in generation of light, as a result, it is possible to make the light switch on by an injection of low electric power. Moreover, it does not emit a light with a long wavelength which will be a factor of temperature increase, but since it emits energy of a single wavelength in a UV region, it has a distinctive feature of suppressing an increase of a surface temperature of an exposure subject. For this reason, it is suitable for flexible film materials, such as polyethylene terephthalate which is supposed to be easily affected by heat.

Oxygen is required for the reaction during UV ray irradiation. Since a vacuum UV ray is absorbed by oxygen, efficiency during the step of UV ray irradiation is likely to decrease. Therefore, irradiation of the vacuum UV rays is preferably carried out at a concentration of oxygen and water vapor being as low as possible. That is, an oxygen concentration is preferably in the range of 10 to 20,000 ppm in volume, and more preferably, it is in the range of 50 to 10,000 ppm in volume.

Further, a water vapor concentration during the conversion process is preferably in the range of 1,000 to 4,000 ppm in volume.

As a gas which is used during vacuum UV ray irradiation and fills an irradiation atmosphere, a dry inactive gas is preferably used. In particular, a dry nitrogen gas is preferable from the viewpoint of cost. The adjustment of an oxygen concentration may be made by measuring a flow rate of an oxygen gas and an inactive gas introduced in an irradiation chamber and by changing a flow rate ratio.

In a step of vacuum UV ray irradiation, illuminance of the aforesaid vacuum UV rays which are received at a coated layer surface of a polysilazane coated layer is preferably in the range of 1 mW/cm² to 10 W/cm², preferably, it is in the range of 30 mW/cm² to 200 mW/cm², and more preferably, it is in the range of 50 mW/cm² to 160 mW/cm². When it is in the range of 1 mW/cm² to 10 W/cm², the reforming efficiency will not be decreased, and there does not occur concern of producing ablation in the coated layer or giving damage to the substrate.

An amount of irradiation energy (irradiation amount) of vacuum UV rays at a coated layer surface is preferably in the range of 10 to 10,000 mJ/cm², more preferably, it is in the range of 100 to 8,000 mJ/cm², still more preferably, it is in the range of 200 to 6,000 mJ/cm². When it is in the range of 10 to 10,000 mJ/cm², sufficient reforming will be done, and there does not occur concern of producing crack due to over reforming or thermal deformation of the substrate.

The vacuum UV rays used for reforming may be generated from plasma which is formed with a gas containing at least one of CO, CO₂ and CH₄.

A gas containing at least one of CO, CO₂ and CH₄ (hereafter, it is also called as “a carbon containing gas”), may be used singly, however, it is preferable to add a small amount of carbon containing gas to a rare gas or a hydrogen gas used as a main gas. Capacitive coupled plasma may be cited as a method of generating plasma.

A layer composition of a polysilazane reforming layer may be determined by measuring an atomic composition ratio with an XPS surface analyzing apparatus. Further, it may be determined by cutting the polysilazane reforming layer, and by measuring an atomic composition ratio at a cross section with an XPS surface analyzing apparatus.

A layer density of a polysilazane reforming layer is appropriately set depending on the purpose. For example, it is preferable to be in the range of 1.5 to 2.6 g/cm³. When it is in this range, compactness of the layer will not be decreased, a gas barrier property will be improved, and oxidation deterioration of the layer by humidity will be prevented.

A polysilazane reforming layer may be a single layer, and it may be used a laminated structure of two or more.

### [Second Gas Barrier Layer]

A second gas barrier layer according to the present invention contains a metal oxide having a metal element selected from the group consisting of: vanadium (V), niobium (Nb), tantalum (Ta), titanium (Ti), zirconium (Zr), hafnium (Hf), magnesium (Mg), yttrium (Y), and aluminum (Al). Particularly, when it contains a metal oxide having niobium, it is possible to achieve high storage property, excellent emission efficiency, and excellent emission uniformity.

A specific material that composes the second gas barrier layer is a metal oxide selected from the group consisting of: vanadium oxide, niobium oxide, tantalum oxide, titanium oxide, zirconium oxide, hafnium oxide, magnesium oxide, yttrium oxide, and aluminum oxide. By placing a metal oxide having a lower redox potential than a redox potential of silicon adjacent to the first gas barrier layer, it is assumed that the metal oxide functions as a reducing agent.

It is preferable that a composition coefficient of an oxygen element contained in the metal oxide is smaller than a stoichiometric value. By this, it is possible to effectively prevent oxidation reaction of Si, N and O contained in the first gas barrier layer. It is thought that the metal oxide will effectively work as a reducing agent.

Here, “a composition coefficient of an oxygen element contained in the metal oxide is smaller than a stoichiometric value” means the following. When the metal oxide is in a completely stoichiometrically oxidized state, and when it is represented by Mₓ₁O_{y1}, the metal oxide of the present invention is represented by Mₓ₂O_{y2}. And, it satisfies the following relationship.

y1/x1>y2/x2 Relationship (1):

In the case of vanadium (V) oxide, since the composition coefficient is stoichiometrically represented by V₂O₅, the value of y1/x1 is 2.5. On the other hand, since the metal oxide of the present invention is not completely oxidized, the composition coefficient of an oxygen element contained in the metal oxide is smaller than a stoichiometric value. The value of y2/x2 becomes smaller than 2.5.

The content of the metal oxide contained in the second gas barrier layer is preferably 50 mass % or more with respect to the total mass of the second gas barrier layer. The content is more preferably 80 mass % or more, still more preferably, it is 95 mass % or more, and still more preferably, it is 98 mass % or more. The most preferably, it is 100 mass %.

A method of forming a second gas barrier layer 13 is not specifically limited. Examples thereof are: physical vapor deposition (PVD) methods such as a sputtering method, a vapor deposition method, and an ion plating method; and chemical vapor deposition (CVD) methods such as plasma CVD method, and an atomic layer deposition (ALD) method.

Among them, formation by a sputtering method is preferable, since it enables to perform layer formation without giving damage to a first gas barrier layer 121 provided at an under position and described later to result in high productivity. Examples of a layer formation by a sputtering method are: a DC (direct current) sputtering method, a RF (high frequency) sputtering method, a combined method of these methods with a magnetron sputtering method, and a dual magnetron sputtering (DMS) method which uses an intermediate frequency range. These known methods may be used alone or in combination of two or more.

A second gas barrier layer 13 may be a single layer, or it may be a laminated structure composed of two or more. When the second gas barrier layer 13 is a laminated structure composed of two or more, the composing layers of the second gas barrier layer 13 may have the same composition, or different composition.

Although a thickness of the second gas barrier layer 13 (when it is a laminated structure, this means the total thickness) is not specifically limited, a preferable thickness is in the range of 1 to 200 nm, a more preferable thickness is in the range of 5 to 50 nm. When the thickness is in this range, it will give a merit of producing an improved effect on a gas barrier property within the range of time (takt time) required for highly productive layer formation.

### [Light Emitting Unit Layer]

A light emitting unit layer 17 is a unit composed of organic functional layer 15 containing at least a light emitting layer as a main component interposed between a pair of electrodes. The electrodes are composed of a first electrode 14 and a second electrode 16. They form a cathode and an anode of an organic EL element. An organic functional layer 15 includes a light emitting layer containing at least an organic material. Further it may be provided with another layer between the light emitting layer and the electrodes.

Preferable specific examples of a layer constitution of various organic functional layers 15 interposed between an anode and a cathode in an organic EL element of the present invention will now be described below, however, the present invention is not limited to these.
(1) Anode/light emitting layer/cathode
(2) Anode/light emitting layer/electron transport layer/cathode
(3) Anode/hole transport layer/light emitting layer/cathode
(4) Anode/hole transport layer/light emitting layer/electron transport layer/cathode
(5) Anode/hole transport layer/light emitting layer/electron transport layer/electron injection layer/cathode
(6) Anode/hole injection layer/hole transport layer/light emitting layer/electron transport layer/cathode
(7) Anode/hole injection layer/hole transport layer/(electron blocking layer)/light emitting layer/(hole blocking layer)/electron transport layer/electron injection layer/cathode

Among these, the embodiment (7) is preferably used. However, the present invention is not limited to this. In the above-described representative element constitution, the layers except the anode and the cathode are organic functional layers 15.

### (Organic Functional Layer)

In the above-described constitutions, the light emitting layer is composed of a single layer or plural layers. When the light emitting layer contains plural layers, a non-light emitting intermediate layer may be placed between the light emitting layers.

In addition, it may be provided with a hole blocking layer (a hole barrier layer) or an electron injection layer (a cathode buffer layer) between the light emitting layer and the cathode. Further, it may be provided with an electron blocking layer (an electron barrier layer) or an hole injection layer (an anode buffer layer) between the light emitting layer and the anode.

An electron transport layer is a layer having a function of transporting an electron. An electron transport layer includes an electron injection layer, and a hole blocking layer in a broad sense. Further, an electron transport layer may be composed of plural layers.

A hole transport layer is a layer having a function of transporting a hole. A hole transport layer includes a hole injection layer, and an electron blocking layer in a broad sense. Further, a hole transport layer may be composed of plural layers.

### (Tandem Structure)

A light emitting unit layer 17 may be a so-called tandem element in which plural organic functional layers each containing at least one light emitting are laminated.

As examples of an organic functional layer 15, it may be cited the above-described layer constitutions of (1) to (7) from which an anode and a cathode are eliminated.

Examples of an element constitution having a tandem structure are as follows:
(1) Anode/first organic functional layer/intermediate layer/second organic functional layer/cathode; and
(2) Anode/first organic functional layer/intermediate layer/second organic functional layer/intermediate layer/third organic functional layer/cathode.

Here, the above-described first organic functional layer, second organic functional layer, and third organic functional layer may be the same or different. It may be possible that two organic functional layers are the same and the remaining one organic functional layer is different.

In addition, the organic functional layers each may be laminated directly or they may be laminated through an intermediate layer. Examples of an intermediate layer are: an intermediate electrode, an intermediate conductive layer, a charge generating layer, an electron extraction layer, a connecting layer, and an intermediate insulating layer. Known composing materials may be used as long as it will form a layer which has a function of supplying an electron to an adjacent layer to the anode, and a hole to an adjacent layer to the cathode.

Examples of a material used in an intermediate layer are: conductive inorganic compounds such as ITO (indium tin oxide), IZO (indium zinc oxide), ZnO₂, TiN, ZrN, HfN, TiO_{X}, VO_{X}, CuI, InN, GaN, CuAlO₂, CuGaO₂, SrCu₂O₂, LaB₆, RuO₂, and Al; a two-layer film such as Au/Bi₂O₃; a multi-layer film such as SnO₂/Ag/SnO₂, ZnO/Ag/ZnO, Bi₂O₃/Au/Bi₂O₃, TiO₂/TiN/TiO₂, and TiO₂/ZrN/TiO₂; fullerene such as C₆₀; and a conductive organic layer such as oligothiophene, metal phthalocyanine, metal-free phthalocyanine, metal porphyrin, and metal-free porphyrin. The present invention is not limited to them.

Examples of a tandem type light emitting unit layer are described in: U.S. Pat. No. 6,337,492, U.S. Pat. No. 7,420,203, U.S. Pat. No. 7,473,923, U.S. Pat. No. 6,872,472, U.S. Pat. No. 6,107,734, U.S. Pat. No. 6,337,492, WO 2005/009087, JP-A 2006-228712, JP-A 2006-24791, JP-A 2006-49393, JP-A 2006-49394, JP-A 2006-49396, JP-A 2011-96679, JP-A 2005-340187, JP Patent 4711424, JP Patent 3496681, JP Patent 3884564, JP Patent 4213169, JP-A 2010-192719, JP-A 2009-076929, JP-A 2008-078414, JP-A 2007-059848, JP-A 2003-272860, JP-A 2003-045676, and WO 2005/094130. The constitutions of the elements and the composing materials are described in these documents, however, the present invention is not limited to them.

Hereafter, each layer which composes a light emitting unit layer 17 will be described.

### [Light Emitting Layer]

A light emitting layer used in an organic EL element 100 is a layer which provide a place of emitting light via an exciton produce by recombination of electrons and holes injected from an electrode or an adjacent layer. The light emitting portion may be either within the light emitting layer or at an interface between the light emitting layer and an adjacent layer thereof.

A total thickness of the light emitting layer is not particularly limited. However, in view of layer homogeneity, required voltage during light emission, and stability of the emitted light color against a drive electric current, a layer thickness is preferably adjusted to be in the range of 2 nm to 5 μm, more preferably, it is in the range of 2 nm to 500 nm, and still most preferably, it is in the range of 5 nm to 200 nm.

Each light emitting layer is preferably adjusted to be in the range of 2 nm to 1 μm, more preferably, it is in the range of 2 nm to 200 nm, and still most preferably, it is in the range of 3 nm to 150 nm.

It is preferable that the light emitting layer incorporates a light emitting dopant (a light emitting dopant compound, a dopant compound, or simply called as a dopant) and a host compound (a matrix material, a light emitting host compound, or simply called as a host).

### (1. Light Emitting Dopant)

As a light emitting dopant used in a light emitting layer, it is preferable to employ: a fluorescence emitting dopant (also referred to as a fluorescent dopant and a fluorescent compound) and a phosphorescence emitting dopant (also referred to as a phosphorescent dopant and a phosphorescent emitting material). Among these, it is preferable that at least one light emitting layer contains a phosphorescence emitting dopant.

A concentration of a light emitting dopant in a light emitting layer may be arbitrarily decided based on the specific dopant employed and the required conditions of the device. A concentration of a light emitting dopant may be uniform in a thickness direction of the light emitting layer, or it may have any concentration distribution.

A light emitting layer may contain plural light emitting dopants. For example, it may use a combination of dopants each having a different structure, or a combination of a fluorescence emitting dopant and a phosphorescence emitting dopant. Any required emission color will be obtained by this.

Color of light emitted by the organic EL element 100 is specified as follows. In FIG. 4.16 on page 108 of “Shinpen Shikisai Kagaku Handbook (New Edition Color Science Handbook)” (edited by The Color Science Association of Japan, Tokyo Daigaku Shuppan Kai, 1985), values determined via a Spectroradiometer CS-2000 (produced by Konica Minolta, Inc.) are applied to the CIE chromaticity coordinate, whereby the color is specified.

It is preferable that the organic EL element 100 exhibits white emission by incorporating one or plural light emitting layers contain plural emission dopants having different emission colors. The combination of emission dopants producing white is not specifically limited. It may be cited, for example, combinations of: blue and orange; and blue, green and red.

It is preferable that “white” in the organic EL element 100 shows chromaticity in the CIE 1931 Color Specification System at 1,000 cd/m² in the region of X=0.39±0.09 and Y=0.38±0.08, when measurement is done to 2-degree viewing angle front luminance via the aforesaid method.

### (1-1. Phosphorescence Emitting Dopant)

The phosphorescence emitting dopant is a compound which is observed emission from an excited triplet state thereof. Specifically, it is a compound which emits phosphorescence at room temperature (25° C.) and exhibits a phosphorescence quantum yield of at least 0.01 at 25° C. The phosphorescence quantum yield is preferably at least 0.1.

The phosphorescence quantum yield will be determined via a method described in page 398 of Bunko II of Dai 4 Han Jikken Kagaku Koza 7 (Spectroscopy II of 4th Edition Lecture of Experimental Chemistry 7) (1992, published by Maruzen Co. Ltd.). The phosphorescence quantum yield in a solution will be determined using appropriate solvents. However, it is only necessary for the phosphorescent dopant of the present invention to exhibit the above phosphorescence quantum yield (0.01 or more) using any of the appropriate solvents.

Two kinds of principles regarding emission of a phosphorescence emitting dopant are cited. One is an energy transfer-type, wherein carriers recombine on a host compound on which the carriers are transferred to produce an excited state of the host compound, and then, via transfer of this energy to a phosphorescent dopant, emission from the phosphorescence emitting dopant is realized. The other is a carrier trap-type, wherein a phosphorescence emitting dopant serves as a carrier trap and then carriers recombine on the phosphorescent dopant to generate emission from the phosphorescent dopant. In each case, the excited state energy of the phosphorescent dopant is required to be lower than that of the host compound.

A phosphorescence emitting dopant may be suitably selected and employed from the known materials used for a light emitting layer for an organic EL element 100.

Examples of a known phosphorescence emitting dopant are compound described in the following publications.

Nature 395, 151 (1998), Appl. Phys. Lett. 78, 1622 (2001), Adv. Mater. 19, 739 (2007), Chem. Mater. 17, 3532 (2005), Adv. Mater. 17, 1059 (2005), WO 2009/100991, WO 2008/101842, WO 2003/040257, US 2006/0202194, US 2007/0087321, and US 2005/0244673.

Inorg. Chem. 40, 1704 (2001), Chem. Mater. 16, 2480 (2004), Adv. Mater. 16, 2003 (2004), Angew. Chem. Int. Ed. 2006, 45, 7800, Appl. Phys. Lett. 86, 153505 (2005), Chem. Lett. 34, 592 (2005), Chem. Commun. 2906 (2005), Inorg. Chem. 42, 1248 (2003), WO 2009/050290, WO 2002/015645, WO 2009/000673, US 2002/0034656, U.S. Pat. No. 7,332,232, US 2009/0108737, US 2009/0039776, U.S. Pat. No. 6,921,915, U.S. Pat. No. 6,687,266, US 2007/0190359, US 2006/0008670, US 2009/0165846, US 2008/0015355, U.S. Pat. No. 7,250,226, U.S. Pat. No. 7,396,598, US 2006/0263635, US 2003/0138657, US 2003/0152802, and U.S. Pat. No. 7,090,928.

Angew. Chem. Int. Ed. 47, 1 (2008), Chem. Mater. 18, 5119 (2006), Inorg. Chem. 46, 4308 (2007), Organometallics 23, 3745 (2004), Appl. Phys. Lett. 74, 1361 (1999), WO 2002/002714, WO 2006/009024, WO 2006/056418, WO 2005/019373, WO 2005/123873, WO 2005/123873, WO 2007/004380, WO 2006/082742, US 2006/0251923, US 2005/0260441, U.S. Pat. No. 7,393,599, U.S. Pat. No. 7,534,505, U.S. Pat. No. 7,445,855, US 2007/0190359, US 2008/0297033, U.S. Pat. No. 7,338,722, US 2002/0134984, and U.S. Pat. No. 7,279,704.

WO 2005/076380, WO 2010/032663, WO 2008/140115, WO 2007/052431, WO 2011/134013, WO 2011/157339, WO 2010/086089, WO 2009/113646, WO 2012/020327, WO 2011/051404, WO 2011/004639, WO 2011/073149, JP-A 2012-069737, JP-A 2012-195554, JP-A 2009-114086, JP-A 2003-81988, JP-A 2002-302671 and JP-A 2002-363552.

Among them, preferable phosphorescence emitting dopants are organic metal complexes containing Ir as a center metal. More preferable are complexes containing at least one coordination mode selected from a metal-carbon bond, a metal-nitrogen bond, a metal-oxygen bond and a metal-sulfur bond.

### (1-2. Fluorescence Emitting Dopant)

A fluorescence emitting dopant is a compound which is capable of emitting light from an excited singlet. It is not specifically limited as long as an emission from an excited singlet is observed.

As fluorescence emitting dopants, listed are compounds such as: an anthracene derivative, a pyrene derivative, a chrysene derivative, a fluoranthene derivative, a perylene derivative, a fluorene derivative, an arylacetylene derivative, a styrylarylene derivative, a styrylamine derivative, an arylamine derivative, a boron complex, a coumarin derivative, a pyran derivative, a cyanine derivative, a croconium derivative, a squarium derivative, an oxobenzanthracene derivative, a fluorescein derivative, a rhodamine derivative, a pyrylium derivative, a perylene derivative, a polythiophene derivative, and a rare earth complex compound.

As a fluorescence emitting dopant, it may be used a light emitting dopant utilizing delayed fluorescence. Specific examples of utilizing delayed fluorescence are compounds described in: WO 2011/156793, JP-A 2011-213643, and JP-A 2010-93181.

### (2. Host Compound)

A host compound is a compound which mainly plays a role of injecting or transporting a charge in a light emitting layer. In an organic EL element 100, an emission from the host compound itself is substantially not observed. Preferably, a host compound is a compound exhibiting a phosphorescent quantum yield of the phosphorescence emission of less than 0.1 at room temperature (25° C.). More preferably, it is a compound exhibiting a phosphorescent quantum yield of less than 0.01. Further, among the compounds incorporated in the light emitting layer, a mass ratio of the host compound in the aforesaid layer is preferably at least 20%.

It is preferable that an exited energy level of a host compound is higher than an exited energy level of a light emitting dopant incorporated in the same layer.

Host compounds may be used singly or may be used in combination of two or more compounds. By using plural host compounds, it is possible to adjust transfer of charge, thereby it is possible to achieve high efficiency of an organic EL element 100.

A host compound used in a light emitting layer is not specifically limited, and known compounds used in organic EL elements may be used. For example, it may be either a low molecular weight compound or a polymer compound having a repeating unit. Further, it may be a compound provided with a reactive group such as a vinyl group and an epoxy group.

A known light emitting host which may be used in the present invention is preferably a compound having a high Tg (a glass transition temperature), from the viewpoint of having a hole transporting ability and an electron transporting ability, as well as preventing elongation of an emission wavelength and increasing heat stability during driving the organic EL element 100 at high temperature. It is preferable that a host compound has a Tg of 90° C. or more, more preferably, has a Tg of 120° C. or more. A glass transition temperature (Tg) is a value obtained using DCS (Differential Scanning Colorimetry) based on the method in conformity to JIS-K-7121.

As specific examples of a host compounds used for the organic EL element 100, the compounds described in the following Documents are cited. However, the present invention is not to them.

Japanese patent application publication (JP-A) Nos. 2001-257076, 2002-308855, 2001-313179, 2002-319491, 2001-357977, 2002-334786, 2002-8860, 2002-334787, 2002-15871, 2002-334788, 2002-43056, 2002-334789, 2002-75645, 2002-338579, 2002-105445, 2002-343568, 2002-141173, 2002-352957, 2002-203683, 2002-363227, 2002-231453, 2003-3165, 2002-234888, 2003-27048, 2002-255934, 2002-260861, 2002-280183, 2002-299060, 2002-302516, 2002-305083, 2002-305084 and 2002-308837; US Patent Application Publication (US) Nos. 2003/0175553, 2006/0280965, 2005/0112407, 2009/0017330, 2009/0030202, 2005/0238919; WO 2001/039234, WO 2009/021126, WO 2008/056746, WO 2004/093 207, WO 2005/089025, WO 2007/063796, WO 2007/063754, WO 2004/107822, WO 2005/030900, WO 2006/114966, WO 2009/086028, WO 2009/003898, WO 2012/023947, JP-A 2008-074939, JP-A 2007-254297 and EP 2034538.

### [Electron Transport Layer]

An electron transport layer used for an organic EL element 100 is composed of a material having a function of transferring an electron. It has a function of transporting an injected electron from a cathode to a light emitting layer.

An electron transport material may be used singly or plural kinds may be used in combination.

A total layer thickness of the electron transport layer is not specifically limited, however, it is generally in the range of 2 nm to 5 μm, and preferably, it is in the range of 2 nm to 500 nm, and more preferably, it is in the range of 5 nm to 200 nm.

In an organic EL element 100, it is known that there occurs interference between the light directly taken from the light emitting layer and the light reflected at the electrode located at the opposite side of the electrode from which the light is taken out at the moment of taking out the light which is produced in the light emitting layer. When the light is reflected at the cathode, it is possible to use effectively this interference effect by suitably adjusting the total thickness of the electron transport layer in the range of several nm to several μm.

On the other hand, the voltage will be increased when the layer thickness of the electron transport layer is made thick. Therefore, especially when the layer thickness is large, it is preferable that the electron mobility in the electron transport layer is 10⁻⁵ cm²/Vs or more.

As a material used for an electron transport layer (hereafter, it is called as an electron transport material), it is only required to have either a property of ejection or transport of electrons, or a barrier to holes. Any of the conventionally known compounds may be selected and they may be employed.

Cited examples are: a nitrogen-containing aromatic heterocyclic derivative, an aromatic hydrocarbon ring derivative, a dibenzofuran derivative, a dibenzothiophene derivative, and a silole derivative.

Examples of the aforesaid nitrogen-containing aromatic heterocyclic derivative are: a carbazole derivative, an azacarbazole derivative,(a compound in which one or more carbon atoms constituting the carbazole ring are substitute with nitrogen atoms), a pyridine derivative, a pyrimidine derivative, a pyrazine derivative, a pyridazine derivative, a triazine derivative, a quinoline derivative, a quinoxaline derivative, a phenanthroline derivative, an azatriphenylene derivative, an oxazole derivative, a thiazole derivative, an oxadiazole derivative, a thiadiazole derivative, a triazole derivative, a benzimidazole derivative, a benzoxazole derivative, and a benzothiazole derivative.

Examples of an aromatic hydrocarbon ring derivative are: a naphthalene derivative, an anthracene derivative, and a triphenylene derivative.

Further, metal complexes having a ligand of a 8-quinolinol structure or dibnenzoquinolinol structure such as tris(8-quinolinol)aluminum (Alq₃), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol)zinc (Znq); and metal complexes in which a central metal of the aforesaid metal complexes is substituted by In, Mg, Cu, Ca, Sn, Ga or Pb, may be also utilized as an electron transport material.

Further, metal-free or metal phthalocyanine, or a compound whose terminal is substituted by an alkyl group or a sulfonic acid group, may be preferably utilized as an electron transport material.

A distyryl pyrazine derivative, which is exemplified as a material for a light emitting layer, may be used as an electron transport material. Further, in the same manner as used for a hole injection layer and a hole transport layer, an inorganic semiconductor such as an n-type Si and an n-type SiC may be also utilized as an electron transport material. It may be used a polymer compound having incorporating any one of these compound in a polymer side chain, or a compound having any one of these compound in a polymer main chain.

Further, in an organic EL element 100, it is possible to employ an electron transport layer of a higher n property (electron rich) which is doped with impurities as a guest material. As examples of a dope material, listed are those described in each of JP-A Nos. 4-297076, 10-270172, 2000-196140, 2001-102175, as well as in J. Appl. Phys., 95, 5773 (2004).

Although the present invention is not limited thereto, preferable examples of a known electron transport material used in an organic EL element 100 are compounds described in the following publications: U.S. Pat. No. 6,528,187, U.S. Pat. No. 7,230,107, US 2005/0025993, US 2004/0036077, US 2009/0115316, US 2009/0101870, US 2009/0179554, WO 2003/060956, WO 2008/132085, Appl. Phys. Lett. 75, 4 (1999), Appl. Phys. Lett. 79, 449 (2001), Appl. Phys. Lett. 81, 162 (2002), Appl. Phys. Lett. 81, 162 (2002), Appl. Phys. Lett. 79, 156 (2001), U.S. Pat. No. 7,964,293, WO 2004/080975, WO 2004/063159, WO 2005/085387, WO 2006/067931, WO 2007/086552, WO 2008/114690, WO 2009/069442, WO 2009/066779, WO 2009/054253, WO 2011/086935, WO 2010/150593, WO 2010/047707, EP 2311826, JP-A 2010-251675, JP-A 2009-209133, JP-A 2009-124114, JP-A 2008-277810, JP-A 2006-156445, JP-A 2005-340122, JP-A 2003-45662, JP-A 2003-31367, JP-A 2003-282270, and WO 2012/115034.

Examples of a more preferable electron transport material are: a pyridine derivative, a pyrimidine derivative, a pyrazine derivative, a triazine derivative, a dibenzofuran derivative, a dibenzothiophene derivative, a carbazole derivative, an azacarbazole derivative, and a benzimidazole derivative.

### [Hole Blocking Layer]

A hole blocking layer is a layer provided with a function of an electron transport layer in a broad meaning. Preferably, it contains a material having a function of transporting an electron, and having very small ability of transporting a hole. It will improve the recombination probability of an electron and a hole by blocking a hole while transporting an electron.

Further, a composition of an electron transport layer described above may be appropriately utilized as a hole blocking layer when needed.

A hole blocking layer placed in an organic EL element 100 is preferably arranged at a location in the light emitting layer adjacent to the cathode side.

In an organic EL element 100, a thickness of a hole blocking layer is preferably in the range of 3 to 100 nm, and more preferably, in the range of 5 to 30 nm.

With respect to a material used for a hole blocking layer, the material used in the aforesaid electron transport layer is suitably used, and further, the material used as the aforesaid host compound is also suitably used for a hole blocking layer.

### [Electron Injection Layer]

An electron injection layer (it is also called as “a cathode buffer layer”) is a layer which is arranged between a cathode and a light emitting layer to decrease an operating voltage and to improve an emission luminance. An example of an electron injection layer is detailed in volume 2, chapter 2 “Electrode materials” (pp. 123-166) of “Organic EL Elements and Industrialization Front thereof (Nov. 30, 1998, published by N.T.S. Co. Ltd.)”.

An electron injection layer is provided in an organic EL element 100 according to necessity, and as described above, it is placed between a cathode and a light emitting layer, or between a cathode and an electron transport layer.

An electron injection layer is preferably a very thin layer. The layer thickness thereof is preferably in the range of 0.1 to 5 nm depending on the materials used. In addition, the layer may be an unequal layer in which the composing material exists intermittently.

An election injection layer is detailed in JP-A Nos. 6-325871, 9-17574, and 10-74586. Examples of a material preferably used in an election injection layer include: a metal such as strontium and aluminum; an alkaline metal compound such as lithium fluoride, sodium fluoride, or potassium fluoride; an alkaline earth metal compound such as magnesium fluoride; a metal oxide such as aluminum oxide; and a metal complex such as lithium 8-hydroxyquinolate (Liq). It is possible to use the aforesaid electron transport materials. The above-described materials may be used singly or plural kinds may be used in an election injection layer.

### [Hole Transport Layer]

A hole transport layer contains a material having a function of transporting a hole. A hole transport layer is a layer having a function of transporting a hole injected from an anode to a light emitting layer.

The total layer thickness of a hole transport layer in an organic EL element 100 is not specifically limited, however, it is generally in the range of 0.5 nm to 5 μm, preferably in the range of 2 nm to 500 nm, and more preferably in the range of 5 nm to 200 nm.

A material used in a hole transport layer (hereafter, it is called as a hole transport material) is only required to have any one of properties of injecting and transporting a hole, and a barrier property to an electron. A hole transport material may be suitably selected from the conventionally known compounds. A hole transport material may be used singly, or plural kinds may be used.

Examples of a hole transport material include: a porphyrin derivative, a phthalocyanine derivative, an oxazole derivative, an oxadiazole derivative, a triazole derivative, an imidazole derivative, a pyrazoline derivative, a pyrazolone derivative, a phenylenediamine derivative, a hydrazone derivative, a stilbene derivative, a polyarylalkane derivative, a triarylamine derivative, a carbazole derivative, an indolocarbazole derivative, an isoindole derivative, an acene derivative of anthracene or naphthalene, a fluorene derivative, a fluorenone derivative, polyvinyl carbazole, a polymer or an oligomer containing an aromatic amine in a side chain or a main chain, polysilane, and a conductive polymer or oligomer (e.g., PEDOT:PSS, aniline type copolymer, polyaniline and polythiophene).

Examples of a triarylamine derivative include: a benzidine type represented by α-NPD, a star burst type represented by MTDATA, a compound having fluorenone or anthracene in a triarylamine bonding core.

A hexaazatriphenylene derivative described in JP-A Nos. 2003-519432 and 2006-135145 may be also used as a hole transport material.

In addition, it is possible to employ an electron transport layer of a higher p property which is doped with impurities. As its example, listed are those described in each of JP-A Nos. 4-297076, 2000-196140, and 2001-102175, as well as in J. Appl. Phys., 95, 5773 (2004).

Further, it is possible to employ so-called p-type hole transport materials, and inorganic compounds such as p-type Si and p-type SiC, as described in JP-A No. 11-251067, and J. Huang et al. reference (Applied Physics Letters 80 (2002), p. 139). Moreover, an orthometal compounds having Ir or Pt as a center metal represented by Ir(ppy)₃ are also preferably used.

Although the above-described compounds may be used as a hole transport material, preferably used are: a triarylamine derivative, a carbazole derivative, an indolocarbazole derivative, an azatriphenylene derivative, an organic metal complex, a polymer or an oligomer incorporated an aromatic amine in a main chain or in a side chain.

Examples of a hole transport material used in an organic EL element 100 are compounds in the aforesaid publications and in the following publications. However, the present invention is not limited to them.

Appl. Phys. Lett. 69, 2160(1996), J. Lumin. 72-74, 985(1997), Appl. Phys. Lett. 78, 673 (2001), Appl. Phys. Lett. 90, 183503 (2007), Appl. Phys. Lett. 51, 913 (1987), Synth. Met. 87, 171 (1997), Synth. Met. 91, 209 (1997), Synth. Met. 111, 421 (2000), SID Symposium Digest, 37, 923 (2006), J. Mater. Chem. 3, 319 (1993), Adv. Mater. 6, 677 (1994), Chem. Mater. 15, 3148 (2003), US 2003/0162053, US 2002/0158242, US 2006/0240279, US 2008/0220265, U.S. Pat. No. 5,061,569, WO 2007/002683, WO 2009/018009, EP 650955, US 2008/0124572, US 2007/0278938, US 2008/0106190, US 2008/0018221, WO 2012/115034, JP-A 2003-519432, JP-A 2006-135145, and U.S. patent application Ser. No. 13/585,981.

### [Electron Blocking Layer]

An electron blocking layer is a layer provided with a function of a hole transport layer in a broad meaning. Preferably, it contains a material having a function of transporting a hole, and having very small ability of transporting an electron. It will improve the recombination probability of an electron and a hole by blocking an electron while transporting a hole.

Further, a composition of a hole transport layer described above may be appropriately utilized as an electron blocking layer of an organic EL element 100 when needed. An electron blocking layer placed in an organic EL element 100 is preferably arranged at a location in the light emitting layer adjacent to the anode side.

A thickness of an electron blocking layer is preferably in the range of 3 to 100 nm, and more preferably, in the range of 5 to 30 nm.

With respect to a material used for an electron blocking layer, the material used in the aforesaid hole transport layer is suitably used, and further, the material used as the aforesaid host compound is also suitably used for an electron blocking layer.

### [Hole Injection Layer]

A hole injection layer (it is also called as “an anode buffer layer”) is a layer which is arranged between an electrode and a light emitting layer to decrease an operating voltage and to improve an emission luminance. An example of a hole injection layer is detailed in volume 2, chapter 2 “Electrode materials” (pp. 123-166) of “Organic EL Elements 100 and Industrialization Front thereof (Nov. 30, 1998, published by N.T.S. Co. Ltd.)”. A hole injection layer is provided according to necessity, and as described above, it is placed between an anode and a light emitting layer, or between an anode and a hole transport layer.

A hole injection layer is also detailed in JP-A Nos. 9-45479, 9-260062 and 8-288069. Materials used in the hole injection layer are the same materials used in the aforesaid hole transport layer. Among them, preferable materials are: a phthalocyanine derivative represented by copper phthalocyanine; a hexaazatriphenylene derivative described in JP-A Nos. 2003-519432 and 2006-135145; a metal oxide represented by vanadium oxide; a conductive polymer such as amorphous carbon, polyaniline (or called as emeraldine) and polythiophene; an orthometalated complex represented by tris(2-phenylpyridine) iridium complex; and a triarylamine derivative.

The above-described materials used in a hole injection layer may be used singly or plural kinds may be used.

### [Other Additive]

An organic functional layer which composes an organic EL element 100 may further contain other additive. Examples of an additive are: halogen elements such as bromine, iodine and chlorine, and a halide compound; and a compound, a complex and a salt of an alkali metal, an alkaline earth metal and a transition metal such as Pd, Ca and Na.

Although a content of an additive may be arbitrarily decided, preferably, it is 1,000 ppm or less based on the total mass of the layer containing the additive, more preferably, it is 500 ppm or less, and still more preferably, it is 50 ppm or less.

In order to improve a transporting ability of an electron or a hole, or to facilitate energy transport of an exciton, the content of the additive is not necessarily within these range, and other range of content may be used.

### [Forming Method of Organic Functional Layer]

It will be described forming methods of organic functional layers of an organic EL element 100 (hole injection layer, hole transport layer, light emitting layer, hole blocking layer, electron transport layer, and electron injection layer).

Forming methods of organic functional layers are not specifically limited. They may be formed by using a known method such as a vacuum vapor deposition method and a wet method (wet process).

Examples of a wet process include: a spin coating method, a cast method, an inkjet method, a printing method, a die coating method, a blade coating method, a roll coating method, a spray coating method, a curtain coating method, and a LB method (Langmuir Blodgett method).

From the viewpoint of getting a uniform thin layer with high productivity, preferable are method highly appropriate to a roll-to-roll method such as a die coating method, a roll coating method, an inkjet method, and a spray coating method.

In a wet process, examples of a liquid medium to dissolve or to disperse a material for an organic functional layer include: ketones such as methyl ethyl ketone and cyclohexanone; aliphatic esters such as ethyl acetate; halogenated hydrocarbons such as dichlorobenzene; aromatic hydrocarbons such as toluene, xylene, mesitylene, and cyclohexylbenzene; aliphatic hydrocarbons such as cyclohexane, decalin, and dodecane; organic solvents such as DMF and DMSO.

These will be dispersed with a dispersion method such as an ultrasonic dispersion method, a high shearing dispersion method and a media dispersion method.

When a vapor deposition method is adopted for forming each layer which composes an organic functional layer, the vapor deposition conditions will change depending on the compounds used. Generally, the following ranges are suitably selected for the conditions, heating temperature of boat: 50 to 450° C., level of vacuum: 10⁻⁶ to 10⁻² Pa, vapor deposition rate: 0.01 to 50 nm/sec, temperature of substrate: −50 to 300° C., and layer thickness: 0.1 nm to 5 μm, preferably 5 to 200 nm.

Formation of an organic EL element 100 is preferably continuously carried out from an organic functional layer to a cathode with one time vacuuming. It may be taken out on the way, and a different layer forming method may be employed. In that case, the operation is preferably done under a dry inert gas atmosphere. In addition, different formation methods may be applied for each layer.

### [First Electrode]

As a first electrode 14, a metal having a large work function (4 eV or more, preferably, 4.3 eV or more), an alloy, and a conductive compound and a mixture thereof are utilized as an electrode substance.

Specific examples of an electrode substance are: metals such as Au and Ag, and an alloy thereof; transparent conductive materials such as CuI, indium tin oxide (ITO), SnO₂, and ZnO. Further, a material such as IDIXO (In₂O₃—ZnO), which will form an amorphous and transparent electrode, may also be used.

As for a first electrode 14, these electrode substances may be made into a thin layer by a method such as a vapor deposition method or a sputtering method; followed by making a pattern of a desired form by a photolithography method. Otherwise, in the case of requirement of pattern precision is not so severe (about 100 μm or more), a pattern may be formed through a mask of a desired form at the time of layer formation with a vapor deposition method or a sputtering method using the above-described material.

Alternatively, when a coatable substance such as an organic conductive compound is employed, it is possible to employ a wet film forming method such as a printing method or a coating method.

When emitted light is taken out from the side of the first electrode 14, the transmittance is preferably set to be not less than 10%. A sheet resistance of a first electrode 14 is preferably a few hundred Ω/sq or less. Further, although a layer thickness of the first electrode 14 depends on a material, it is generally selected in the range of 10 nm to 1 μm, and preferably in the range of 10 to 200 nm.

Specifically, it is preferable that the first electrode 14 is a layer composed of silver as a main ingredient, and it is preferably made of silver or an alloy containing silver as a main component.

As a forming method of the first electrode 14 as described above, it may be cited: wet processes such as an application method, an inkjet method, a coating method and a dip method; and dry processes such as a vapor deposition method (resistance heating, EB method), a sputtering method, and CVD. Among them, a vapor deposition method is preferably used.

Examples of an alloy which contains silver (Ag) as a main component for forming the first electrode 14 are: silver magnesium (AgMg), silver copper (AgCu), silver palladium (AgPd), silver palladium copper (AgPdCu) and silver indium (AgIn).

The above-described first electrode 14 may have a constitution in which plural layers made of silver or an alloy containing silver as a main component are separately made and they are laminated according to necessity.

Further, a preferable thickness of this first electrode 14 is in the range of 4 to 15 nm. When it is 15 nm or less, an absorbing component and a reflection component of the layer may be kept at low level, and as a result, a transparency of the transparent barrier layer will be maintained, which is preferable. By making the thickness to be 4 nm or more, the conductivity of the layer will be also maintained.

In the case of forming a layer composed of silver as a main component as a first electrode 14, it may form an underlayer of the first electrode 14. The underlayer may be other conductive layer containing Pd, or an organic layer containing a nitrogen compound or a sulfur compound. By forming an underlayer, it will improve a layer forming property of a layer composed of silver as a main component; it will decrease resistivity of the first electrode 14; and it will improve transparency of the first electrode 14.

### [Second Electrode]

As a second electrode 16, a metal having a small work function (4 eV or less) (it is called as an electron injective metal), an alloy, a conductive compound and a mixture thereof are utilized as an electrode substance.

Specific examples of the aforesaid electrode substance includes: sodium, sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, aluminum, and a rare earth metal.

Among them, with respect to an electron injection property and durability against oxidation, preferable are: a mixture of election injecting metal with a second metal which is stable metal having a work function larger than the electron injecting metal. Examples thereof are: a magnesium/silver mixture, a magnesium/aluminum mixture, a magnesium/indium mixture, an aluminum/aluminum oxide (Al₂O₃) mixture, a lithium/aluminum mixture and aluminum.

The second electrode 16 may be made by using these electrode substances with a method such as a vapor deposition method or a sputtering method. A sheet resistance of a second electrode 15 is preferably a few hundred Ω/sq or less. Further, a layer thickness of the second electrode 16 is generally selected in the range of 10 nm to 5 μm, and preferably in the range of 50 to 200 nm.

Further, after forming a layer of the aforesaid metal having a thickness of 1 to 20 nm on the second electrode 16, it is possible to prepare a transparent or translucent second electrode 16 by providing with a conductive transparent material described in the description for First electrode thereon. By applying this process, it is possible to produce an element in which both a first electrode 14 and a second electrode 16 are transparent.

### [Covering Layer]

A covering layer 18 spreads over the light emitting unit layer 17, which is disposed on the second gas barrier layer 13. The covering layer 18 is formed so as to cover the whole light emitting unit layer 17 with the covering layer 18 and the second gas barrier layer 13.

The covering layer 18 is a member which seals the light emitting unit layer 17 with a sealing adhesive layer 19.

Therefore, the covering layer 18 is preferably formed by using a material having a function of preventing penetration of water or oxygen which will deteriorate the light emitting unit layer 17.

Further, the covering layer 18 is a constitution component which directly comes in contact with the second gas barrier layer 13 and sealing adhesive layer 19. Therefore, it is preferable to use a material excellent in joining ability with the second gas barrier layer 13 and sealing adhesive layer 19.

As a covering layer 18, it is preferably formed with a compound such as inorganic oxide, inorganic nitride, and inorganic carbide having a high sealing property.

Specifically, it may be formed with: SiOₓ, Al₂O₃, In₂O₃, TiOₓ, ITO (indium tin oxide), AlN, Si₃N₄, SiOₓN, TiOₓN, and SiC.

The covering layer 18 may be formed with a known method such as a sol-gel method, a vapor deposition method, CVD, ALD (Atomic Layer Deposition), PVD and a sputtering method.

The covering layer 18 may be formed with an atmospheric pressure plasma method by selecting conditions of: an organic metal compound as a raw ingredient (it is called as a raw material), a decomposition gas, a decomposition temperature, an input electric power. By a suitable selection, it is possible to selectively make a composition of: silicon oxide, inorganic oxide mainly composed of silicon oxide, inorganic oxynitride, inorganic oxyhalide, inorganic carbide, inorganic nitride, inorganic sulfide, and mixture of inorganic halides.

For example, if a silicon compound is used as a raw material compound and oxygen is used for a decomposition gas, a silicon oxide will be generated. Moreover, if silazane is used as a raw material compound, silicon oxynitride will be generated. The reason of this is as follows. In a plasma space, there exist very active charged particles and active radicals in a high density, as a result, a chemical reaction of multi-steps will be extremely accelerated in a plasma space to result in converting into a thermodynamically stable compound in an extremely short time.

As a raw material for forming the above-described covering layer 18, it may be used any silicon compounds of gas, liquid and solid sates at ambient temperature and pressure. When it is a gas, it may be introduced as it is in the plasma space, however, when it is a liquid or a solid, it is used after evaporating with a means such as heating, bubbling, reduced pressure or ultrasonic irradiation. Moreover, it may be used by diluting with a solvent, and organic solvents such as methanol, ethanol, and n-hexane, and a mixed solvent thereof may be used as a solvent. In addition, since these diluting solvents are decomposed into a state of a molecule or an atom during a plasma electric discharge process, their influences will be almost disregarded.

Examples of such a silicon compound are cited as: silane, tetramethoxysilane, tetraethoxysilane, tetra-n-propoxysilane, tetraisopropoxysilane, tetra-n-butoxysilane, tetra-t-butoxysilane, dimethyldimethoxysilane, dimethyldiethoxysilane, diethyldimethoxysilane, diphenyl dimethoxysilane, methyl triethoxysilane, ethyl trimethoxysilane, phenyltriethoxysilane, (3,3,3-trifluoropropyl)trimethoxysilane, hexamethyldisiloxane, bis(dimethylamino)dimethylsilane, bis(dimethylamino)methylvinylsilane, bis(ethylamino)dimethylsilane, N,O-bis(trimethylsilyl)acetamide, bis(trimethylsilyl)carbodiimide, diethylaminotrimethylsilane, dimethylaminodimethylsilane, hexamethyldisilazane, hexamethylcyclotrisilazane, heptahexamethyldisilazane, nona methyltrisilazane, octamethylcyclotetrasilazane, tetrakisdimethylaminosilane, tetraisocyanatesilane, tetramethyldisilazane, tris(dimethylamino)silane, triethoxyfluorosilane, allyldimethylsilane, allyltrimethylsilane, benzyltrimethylsilane, bis(trimethylsilyl)acetylene, 1,4-bistrimethylsilyl-1,3-butadiyne, di-t-butylsilane, 1,3-disilabutane, bis(trimethylsilyl)methane, cyclopentadienyltrimethylsilane, phenyldimethylsilane, phenyltrimethylsilane, propargyltrimethylsilane, tetramethylsilane, trimethylsilylacetylene, 1-(trimethylsilyl)-1-propyne, tris(trimethylsilyl)methane, tris(trimethylsilyl)silane, vinyltrimethylsilane, hexamethyldisilane, octamethylcyclotetrasiloxane, tetramethylcyclotetrasiloxane, hexamethyl cyclotetrasiloxane, and M silicate 51.

Examples of a decomposition gas which decomposes these raw material gasses containing silicon and produces a covering layer 18 are: hydrogen gas, methane gas, acetylene gas, carbon monoxide gas, carbon dioxide gas, nitrogen gas, ammonia gas, nitrous oxide gas, nitrogen oxide gas, nitrogen dioxide gas, oxygen gas, water vapor, fluorine gas, hydrogen fluoride, trifluoroacetic alcohol, trifluorotoluene, hydrogen sulfide, sulfur dioxide, carbon disulfide, and chlorine gas.

By suitably selecting a raw material gas containing silicon and a decomposition gas, it may be obtained a covering layer 18 containing silicon oxide, nitride or carbide.

It is used a nitrogen gas or elements of group 18 in the periodic table as a discharge gas. Specifically, it is used: helium, neon, argon, krypton, xenon or radon. Of these, nitrogen, helium and argon are preferably used.

The above-described discharge gas and a reactive gas are mixed, and this is supplied as a thin layer forming (mixture) gas in an atmospheric pressure plasma generating apparatus (plasma generating apparatus) to result in formation of a layer. Although a ratio of a discharge gas to a reactive gas will be different depending on the layer property to be obtained, a reactive gas is supplied so that a ratio of a discharge gas is made to be 50% or more based on the total mixture gas.

### [Sealing Adhesive Layer]

A sealing adhesive layer 19 for fixing the sealing member 20 to a side of the flexible substrate 11 is used for sealing the organic EL element 100 interposed between the sealing member 20 and the flexible substrate 11. Examples of an adhesive contained in the sealing adhesive layer 19 are: a heat-curable adhesive having a reactive vinyl group of an acrylic acid oligomer or a methacrylic acid oligomer; and an epoxy-type heat-curable adhesive.

As a form of a sealing adhesive layer 19, it is preferable to use a sheet-form heat-curable adhesive. When a sheet-form heat-curable adhesive is used, an adhesive (a sealing material) is a material exhibiting non-fluidity at normal temperature (about 25° C.), and exhibiting fluidity when it is heated at a temperature in the range of 50 to 130° C.

As a heat-curable adhesive, any adhesives may be used. From the viewpoint of increasing close contact of the sealing adhesive layer 19 with the adjacent second gas barrier layer 13, the covering layer 18, and the sealing member 20, a suitable heat-curable adhesive may be selected. As a heat-curable adhesive, it may be used a resin containing as a main component: a compound having an ethylenic double bond at an end or a side chain of the molecule; and a thermal polymerization initiator.

More specifically, it may be used a heat-curable adhesive composed of an epoxy resin and an acrylic resin. Further, a melt type heat-curable adhesive may be used in accordance with an adhesion apparatus and a hardening treatment apparatus used in the production step of an organic EL element 100.

As an adhesive, it may be used a mixture of two or more kinds of the aforesaid adhesives. And it may be used an adhesive having both a heat-curable property and a UV-curable property.

### [Sealing Member]

A sealing member 20 covers an organic EL element 100. A sealing member 20 of a plate type (film type) is fixed to a side of a flexible substrate 11 via a sealing adhesive layer 19. This sealing member 20 is provided in a manner that the edge portions of the organic EL element 100 and the second electrode 16 (not indicated in the figure) are exposed. Otherwise, it may be provided in a manner that an electrode is placed on the sealing member 20, and the edge portions of the organic EL element 100 and the second electrode 16 are made in a conduction state with this electrode.

As a sealing member 20, it is preferable to use a metal foil laminated with a resin film (polymer layer). The metal foil laminated with a resin film may not be used for a flexible substrate 11 placed at a side from which light is taking out, however, it is low cost and it is a sealing material of low moisture permeability. Therefore, it is suitable for a sealing member 20 which is not intended to take out light.

“A metal foil” in the present invention indicates a foil or a film made of a metal which is produced by a process such as rolling. This is different from: a metal thin layer formed with a sputtering method or a vapor deposition method; or a conductive layer formed by using a fluid electrode material such as a conductive paste.

As a metal foil, the kind of metal is not specifically limited. Examples thereof are: copper (Cu) foil, aluminum (Al) foil, gold (Au) foil, brass foil, nickel (Ni) foil, titanium (Ti) foil, copper alloy foil, stainless steel foil, tin (Sn) foil, and high nickel alloy foil. Among these foils, specifically preferred metal foil is an aluminum (Al) foil.

A thickness of metal foil is preferably in the range of 6 to 50 μm. When it is less than 6 μm, it may generate pinholes which are produced depending on the used material for metal foil, and required gas barrier properties (vapor permeability and oxygen permeability) may not be obtained. When it is larger than 50 μm, it will increase a cost and thickness of the organic EL element 100 will be large. Thus, it will decrease the advantage of using a film-type sealing member.

Resin films usable in a metal foil composed of a resin film are described in “New development of functional enveloping materials” (Toray Research, Co. Ltd.)

Examples of a resin for a resin film are: a polyethylene resin, a polypropylene resin, a polyethylene terephthalate resin, a polyamide resin, an ethylene-vinyl alcohol copolymer resin, an ethylene-vinyl acetate copolymer resin, an acrylonitrile-butadiene copolymer resin, a cellophane resin, a vinylon resin, and a vinylidene chloride resin.

A polypropylene resin and a Nylon resin may be stretched, and further, they may be coated with a vinylidene chloride resin. Any one of high density or low density polyethylene resin may be used.

As a sealing member 20, it may be used a plate type or film type substrate. Specific examples are a glass substrate and a polymer substrate. These substrate materials may be further made to be a thin film. Examples of a glass substrate include: soda-lime glass, barium-strontium containing glass, lead glass, aluminosilicate glass, borosilicate glass, barium borosilicate glass, and quartz. Further, listed examples of a polymer substrate are: polycarbonate, acryl, polyethylene terephthalate, polyether sulfide, and polysulfone. Among these, a polymer substrate of a thin film state is preferably used from the viewpoint of making the element to be thin.

The sealing member 20 is preferably provided with the following properties: an oxygen permeability of 1×10⁻³ ml/(m²·24 h·atm) or less, determined based on JIS K 7126-1987; and a water vapor permeability of 1×10⁻³ g/(m²·24 h) or less (25±0.5° C., and relative humidity (90±2) % RH) determined based on JIS K 7129-1992.

The aforesaid substrate materials may be processed to form a concave form to become a sealing member 20. In this case, a concave form is formed by carrying out a process such as a sand blast process or a chemical etching process to the aforesaid substrate materials.

A metal material may be used other than these materials. Examples of a metal material are: those composed of at least one metal selected from the group consisting of stainless steel, iron, copper, aluminum, magnesium, nickel, zinc, chromium, titanium, molybdenum, silicon, germanium, and tantalum, or alloys thereof. These metal materials are made into a thin film, and they are used as a sealing member 18. Thus, an entire light emitting panel provided with an organic EL element 100 will be made thinner.

### [Applications]

An organic EL element 100 may be applied to: a display device, a display, and an electronic device such as various light emission sources.

Examples of a light emission source includes: a home use illumination, a car room illumination, a backlight of a watch or a liquid crystal, a panel advertisement, a signal, a light source for an optical memory medium, a light source for an electrophotographic copier, a light source for an optical telecommunication processor, and a light source for a photo-sensor. However, the present invention is not limited thereto. In particular, it may be effectively used for a backlight for a liquid crystal and an illumination source.

If needed, the organic EL element 100 may be subjected to patterning via a metal mask or an inkjet printing method during film formation. When the patterning is carried out, only an electrode may undergo patterning, an electrode and a light emitting layer may undergo patterning, or all element layers may undergo patterning. During preparation of the element, it is possible to employ conventional methods.

### 2. Organic Electroluminescent Element (Second Embodiment)

### [Constitution of Organic EL Element]

Next, a second embodiment will be described. A schematic constitution of an organic electroluminescent element of the second embodiment is illustrated in FIG. 2.

The organic EL element 200 has the same constitution as the above-described first embodiment, except that the third gas barrier layer 21 is placed between the flexible substrate 11 and the first gas barrier layer 12. Therefore, in the following description, an overlapping explanation described in an organic EL element of a first embodiment is omitted. A constitution of an organic EL element of a second embodiment will be described in the following.

### [Third Gas Barrier Layer]

The third gas barrier layer 21 is not limited as long as it has a gas barrier property. Preferably, it is a layer composed of a silicon compound which further contains at least one element selected from the group consisting of carbon (C), nitrogen (N) and oxygen (O). By being provided with the third gas barrier layer 21, the sealing property is further increased, and it may be obtained an effect of effectively preventing the generation of a non-luminous portion.

It is sufficient that the third gas barrier layer has the following properties: a water vapor permeability of 0.01 g/(m²·24 h) or less (25±0.5° C., and relative humidity (90±2) % RH) determined based on JIS K 7129-1992. In addition, a water vapor permeability is preferably 0.001 g/(m²·24 h) or less.

From the viewpoint of increased gas barrier property, the silicon compound which composes the third gas barrier layer 21 has preferably a continuous composition change from a surface to a thickness direction by changing an element ratio, the element being at least one selected from the group consisting of C, N and O.

In addition, the silicon compound which composes the second gas barrier layer 21 has preferably at least one extreme value (extremum) in this continuous composition change in the thickness direction from the viewpoint of gas barrier property and bending resistance property. Namely, the second gas barrier layer 21 is preferably composed of materials containing silicon, oxygen and carbon, and it has regions each has a different content of silicon, oxygen and carbon.

### (Conditions of Distribution Curve of Each Element)

It is preferable that atomic percentages of silicon, oxygen and carbon, and distribution curves of each element in the third gas barrier layer 21 will satisfy the following conditions (i) to (iii).
(i) The atomic percentages of silicon, oxygen, and carbon satisfy the relationship (A1) indicated below in an area covering 90% or more of the distance from the surface across the thickness of the third gas barrier layer 21.

(Atomic percentage of oxygen)>(atomic percentage of silicon)>(atomic percentage of carbon) Relationship (A1):

Otherwise, the atomic percentages of silicon, oxygen, and carbon satisfy the relationship (A2) indicated below in an area covering 90% or more of the distance from the surface across the thickness of the third gas barrier layer 21.

(Atomic percentage of carbon)>(atomic percentage of silicon)>(atomic percentage of oxygen) Relationship (A2):
(ii) The carbon distribution curve has at least two local extremum points (a local maximum and a local minimum).
(iii) The absolute value of the difference between the maximum value and the minimum value of the atomic percentage of carbon in the carbon distribution curve is 5 at % or more.

It is preferable that the organic EL element of the present invention is provided with a second gas barrier layer satisfying at least one of the above-described conditions (i) to (iii). In particular, it is preferable that the organic EL element is provided with a third gas barrier layer 21 satisfying all of the above-described conditions (i) to (iii).

In addition, the organic EL element may be provided with two or more third gas barrier layers 21 satisfying all of the above-described conditions (i) to (iii). When the organic EL element is provided with two or more third gas barrier layers 21, the material of the thin layer in the plural third gas barrier layers 21 may be the same or different.

The refractive index of the third gas barrier layer 21 may be regulated by an atomic percentage of carbon or oxygen. Consequently, the refractive index of the third gas barrier layer 21 may be adjusted in the required range by the above-described conditions (i) to (iii).

### (Carbon Distribution Curve)

The third gas barrier layer 21 is required to have a carbon distribution curve containing at least one extremum point. More preferably, the third gas barrier layer 21 has a carbon distribution curve containing at least two extremum points. In particular, still more preferably, a carbon distribution curve contains at least three extremum points. Further, it is preferable that the carbon distribution curve contains at least one local maximum point and one local minimum point.

When the carbon distribution curve contains an extremum point, the light distribution of the obtained third gas barrier layer 21 may be increased. As a result, it may solve the problem of the viewing angle dependency of the emitted light from the organic EL element obtained through the first electrode 14.

When the third gas barrier layer 21 contains three or more extremum points, it is preferable that the distance between one extremum point and an adjacent extremum point in the carbon distribution curve is 200 nm or less in the thickness direction from the surface of the third gas barrier layer 21. More preferably, it is 100 nm or less from the viewpoint of improving the light distribution and releasing stress in the third gas barrier layer 21.

### (Extremum)

Extremum points in the atomic distribution curve of the third gas barrier layer 21 refer to measured values of local maximum points or local minimum points of the atomic percentage of each element at a certain distance from the surface of the third gas barrier layer 21 in the thickness direction of the third gas barrier layer 21. Or, they are the measured values of a refractive index distribution curve corresponding to these values.

The local maximum point in the distribution curve of each element of the third gas barrier layer 21 represents a point at which the atomic percentage of the element changes from an increase to a decrease when the distance from the surface of the third gas barrier layer 21 varies, and from which point the atomic percentage of the element decreases by 3 at % or more when the distance from the surface of the third gas barrier layer 21 in the thickness direction varies by 20 nm.

The local minimum point in the distribution curve of each element of the third gas barrier layer 21 represents a point at which the atomic percentage changes from a decrease to an increase when the distance from the surface of the third gas barrier layer 21 varies, and from which point the atomic percentage of the element increases by 3 at % or more when the distance from the surface of the third gas barrier layer 21 in the thickness direction varies by 20 nm.

In a carbon distribution curve of the third gas barrier layer 21, it is preferable that an absolute value of the difference between the maximum value and the minimum value of the atomic percentage of carbon is 5 at % or more. In the third gas barrier layer 21, it is more preferable that an absolute value of the difference between the maximum value and the minimum value of the atomic percentage of carbon is 6 at % or more. And still more preferably, it is 7 at % or more. When the difference between the maximum value and the minimum value of the atomic percentage of carbon is in the above-described range, the difference of refractive index in a refractive index distribution curve of the obtained third gas barrier layer 21 becomes large, and light distribution becomes sufficient.

There is correlation between a carbon distribution amount and a refractive index. When the absolute value of the difference between the maximum value and the minimum value of carbon is 7 at % or more, the obtained absolute value of the difference between the maximum value and the minimum value of refractive index becomes 0.2 or more.

### (Oxygen Distribution Curve)

The third gas barrier layer 21 is required to have an oxygen distribution curve containing at least one extremum point. More preferably, the third gas barrier layer 21 has an oxygen distribution curve containing at least two extremum points. In particular, still more preferably, an oxygen distribution curve contains at least three extremum points. Further, it is preferable that the oxygen distribution curve contains at least one local maximum point and one local minimum point.

When the oxygen distribution curve contains an extremum point, the light distribution of the obtained third gas barrier layer 21 may be increased. As a result, it may solve the problem of the viewing angle dependency of the emitted light from the organic EL element obtained through the first electrode.

When the third gas barrier layer 21 has three or more extremum points, it is preferable that the distance between one extremum point and an adjacent extremum point in the carbon distribution curve is 200 nm or less in the thickness direction from the surface of the second gas barrier layer 122. More preferably, it is 100 nm or less from the viewpoint of improving the light distribution and releasing stress in the third gas barrier layer 21.

In an oxygen distribution curve of the third gas barrier layer 21, it is preferable that an absolute value of the difference between the maximum value and the minimum value of the atomic percentage of oxygen is 5 at % or more. In the third gas barrier layer 21, it is more preferable that an absolute value of the difference between the maximum value and the minimum value of the atomic percentage of oxygen is 6 at % or more. And still more preferably, it is 7 at % or more. When the difference between the maximum value and the minimum value of the atomic percentage of oxygen is in the above-described range, the light distribution becomes sufficient based on the refractive index distribution curve of the obtained third gas barrier layer 21.

### (Silicon Distribution Curve)

In a silicon distribution curve of the third gas barrier layer 21, it is preferable that an absolute value of the difference between the maximum value and the minimum value of the atomic percentage of silicon is less than 5 at %. More preferably, an absolute value of the difference between the maximum value and the minimum value of the atomic percentage of silicon in the third gas barrier layer 21 is less than 4 at %. Still more preferably, it is less than 3 at %. When the difference between the maximum value and the minimum value of the atomic percentage of silicon is in the above-described ranges, the light distribution becomes sufficient based on the refractive index distribution curve of the obtained third gas barrier layer 21.

### (Sum of Oxygen and Carbon: Oxygen-Carbon Distribution Curve)

In the third gas barrier layer 21, a percentage of a sum of oxygen and carbon with respect to a sum of silicon, oxygen and carbon is called as “an oxygen-carbon distribution curve”.

In an oxygen-carbon distribution curve of the third gas barrier layer 21, it is preferable that an absolute value of the difference between the maximum value and the minimum value of the atomic percentage of the sum of oxygen and carbon is less than 5 at %. More preferably, it is less than 4 at %. Still more preferably, it is less than 3 at %. When the difference between the maximum value and the minimum value of the atomic percentage of the sum of oxygen and carbon is in the above-described ranges, the light distribution becomes sufficient based on the refractive index distribution curve of the obtained third gas barrier layer 21.

### (XPS Depth Profiling)

The above-described silicon, oxygen, carbon, oxygen-carbon, and nitrogen distribution curves will be prepared through XPS depth profiling in which the interior of the specimen is exposed in sequence for analysis of the surface composition through a combination of X-ray photoelectron spectroscopy (XPS) and ion-beam sputtering using a rare gas, such as argon.

Each distribution curve acquired through such XPS depth profiling has, for example, a vertical axis representing the atomic percentage (unit: at %) of the element and a horizontal axis representing the etching time (sputtering time).

In a distribution curve of an element having an etching time as a horizontal axis, the etching time correlates approximately with the distance from the surface of the third gas barrier layer 21 in the thickness direction of the gas barrier layer. Thus, a distance from the surface of the third gas barrier layer 21 calculated on the basis of the relationship between the etching rate and etching time used in the XPS depth profiling may be adopted “as a distance from the surface of the third gas barrier layer 21 in the thickness direction”.

For the XPS depth profiling, it is preferable to select an ion-beam sputtering of a rare gas using argon (Ar⁺) as an ionic species and an etching rate of 0.05 nm/sec (equivalent to a value for a thermally-oxidized SiO₂ film).

From the viewpoint of forming a gas barrier layer having a uniform layer and superior light distribution property, it is preferable that the third gas barrier layer 21 is substantially uniform in the direction of the film surface (the direction parallel to the surface of the third gas barrier layer 21).

In this specification, a third gas barrier layer 21 being substantially uniform in the direction of the film surface means the following. At any two points of the third gas barrier layer 21, the element distribution curves for the two points contain the same number of extremum points, and the absolute values of the differences between the maximum value and the minimum value of the atomic percentage of carbon in the carbon distribution curves are identical or have a difference of 5 at % or less.

### (Substantial Continuity)

In the third gas barrier layer 21, the carbon distribution curve preferably has substantial continuity.

In this specification, the carbon distribution curve having substantial continuity means that the variation in the atomic percentage of carbon in the carbon distribution curve does not include any discontinuity. Specifically, it means that the condition represented by the following mathematical expression (F1) is satisfied, F1 being the relationship between the distance x (in nm) from the surface of the third gas barrier layer 21 in the thickness direction, which is derived from the etching rate and the etching time, and the atomic percentage of carbon (C in at %).

(dC/dx)≦0.5 Relationship (F1):

### (Atomic Percentage of Silicon Atom, Oxygen Atom and Carbon Atom)

In the silicon, oxygen, and carbon distribution curves, it is preferable that atomic percentages of silicon, oxygen, and carbon will satisfy the condition represented by the above-described relationship (1) in an area corresponding to 90% or more of the thickness of the third gas barrier layer 21.

In this case, the atomic percentage of silicon atom to the total amount of silicon atom, oxygen atom and carbon atom in the third gas barrier layer 21 is preferably in the range of 25 to 45 at %, more preferably in the range of 30 to 40 at % from the viewpoint of improving gas barrier property.

The atomic percentage of oxygen atom to the total amount of silicon atom, oxygen atom and carbon atom in the third gas barrier layer 21 is preferably in the range of 33 to 67 at %, more preferably in the range of 45 to 67 at % from the viewpoint of improving gas barrier property and transmittance of light.

The atomic percentage of carbon atom to the total amount of silicon atom, oxygen atom and carbon atom in the third gas barrier layer 21 is preferably in the range of 3 to 33 at %, more preferably in the range of 3 to 25 at % from the viewpoint of improving gas barrier property and transmittance of light.

The third gas barrier layer 21 may be formed by a known method described in JP-A 2014-226894.

### EXAMPLES

Hereafter, the present invention will be described specifically by referring to Examples, however, the present invention is not limited to them. In Examples, the term “parts” or “%” is used. Unless particularly mentioned, they respectively represent “mass parts” or “mass %”.

### <<Production Method of Organic EL Element>>

### [Flexible Substrate]

The following substrate was used as a flexible substrate: A PET film provided with hard coat layers on both surfaces of the PET film (total thickness: 136 μm).

### [First Gas Barrier Layer]

A first barrier layer was prepared under the film forming conditions a1 or a2 as indicated below.

### (Film Forming Condition a1)

First, a dibutyl ether solution containing 20 mass % of perhydropolysilazane (NN120-20, made by AZ Electronic Materials Co.,) and a dibutyl ether solution containing 20 mass % of perhydropolysilazane and an amine catalyst (N,N,N′,N′-tetramethyl-1,6-diaminohexane (TMDHA)) (NAX 120-20, made by AZ Electronic Materials Co.,) were mixed with a ratio of 4:1 (mass ratio). Then, a suitable amount of dibutyl ether was added to adjust a dry layer thickness. Thus, each coating solution was prepared.

A coating solution was applied with a spin coat method to achieve a layer of a dried layer thickness of 250 nm, then, the layer was dried at 80° C. for 2 minutes.

Subsequently, a surface treatment was performed to the dried coated layer with a vacuum UV irradiation (wavelength: 172 nm; Excimer lamp, 3.0 J/cm²).

### (Film Forming Condition a2)

On the first gas barrier layer formed by the film forming condition al was applied a coating solution with a spin coat method to achieve a layer of a dried layer thickness of 500 nm, then, the layer was dried at 80° C. for 2 minutes.

Subsequently, a surface treatment was performed to the dried coated layer with a vacuum UV irradiation (wavelength: 172 nm; Excimer lamp, 3.0 J/cm²).

### [Second Gas Barrier Layer]

The flexible substrate having a first gas barrier layer was placed in a chamber of an RF sputtering apparatus. A second gas barrier layer containing a predetermined metal oxide was formed under any one of the film forming conditions b1 to b14 indicated in the following Table 1. Here, the composition coefficient of an oxygen element contained in the metal oxide is obtained by elemental analysis using XPS analysis. The layer thickness was determined with cross-section TEM.

TABLE 1

| | | | | | Composition | Composition |
|---|---|---|---|---|---|---|
| | | | | | coefficient | coefficient |
| Film | | Ar gas | O₂ gas | | of oxygen | of oxygen |
| forming | | supplying | supplying | Layer | element | element |
| condition | | amount | amount | thickness | (Measured | (Stoichiometric |
| No. | Material | (SCCM) | (SCCM) | (nm) | value) | value) |
| b1 | Vanadium oxide (V₂O₅) | 20.0 | 3.5 | 15 | 2.5 | 2.5 |
| b2 | Niobium oxide (Nb₂O₅) | 20.0 | 3.5 | 15 | 2.5 | 2.5 |
| b3 | Tantalum oxide (Ta₂O₅) | 20.0 | 3.2 | 15 | 2.3 | 2.5 |
| b4 | Titanium oxide (TiO₂) | 20.0 | 2.5 | 15 | 1.8 | 2.0 |
| b5 | Zirconium oxide (ZrO₂) | 20.0 | 2.5 | 15 | 1.8 | 2.0 |
| b6 | Hafnium oxide (HfO₂) | 20.0 | 2.5 | 15 | 1.8 | 2.0 |
| b7 | Magnesium oxide (MgO) | 20.0 | 1.4 | 15 | 1.0 | 1.0 |
| b8 | Yttrium oxide (Y₂O₃) | 20.0 | 2.1 | 15 | 1.5 | 1.5 |
| b9 | Aluminum oxide (Al₂O₃) | 20.0 | 2.1 | 15 | 1.5 | 1.5 |
| b10 | Aluminum oxide (Al₂O₃) | 20.0 | 2.0 | 15 | 1.4 | 1.5 |
| b11 | Niobium oxide (Nb₂O₅) | 20.0 | 3.0 | 15 | 2.2 | 2.5 |
| b12 | Niobium oxide (Nb₂O₅) | 20.0 | 3.3 | 15 | 2.4 | 2.5 |
| b13 | Niobium oxide (Nb₂O₅) | 20.0 | 3.3 | 30 | 2.4 | 2.5 |
| b14 | Niobium oxide (Nb₂O₅) | 20.0 | 3.3 | 5 | 2.4 | 2.5 |

### [Light Emitting Unit Layer]

A substrate formed with a second gas barrier layer beforehand was fixed to a substrate holder of a vacuum deposition apparatus available on the market. Then, a nitrogen containing compound as indicated below was placed in a tungsten resistance heating boat. The substrate holder and the heating boat were placed in the first vacuum tank of the vacuum deposition apparatus.

Silver (Ag) was placed in another tungsten resistance heating boat, and it was placed in a second vacuum tank of the vacuum deposition apparatus.

Subsequently, after reducing the pressure of the first vacuum tank to 4×10⁻⁴ Pa, the aforesaid heating boat in which the nitrogen containing compound was placed was heated via application of electric current, and a nitrogen containing layer was formed onto the substrate at a deposition rate of 0.1 to 0.2 nm/second with a thickness of 10 nm.

Subsequently, the substrate formed with the nitrogen containing layer was transported in the second vacuum tank. After reducing the pressure of the second vacuum tank to 4×10⁻⁴ Pa, the aforesaid heating boat in which silver (Ag) was placed was heated via application of electric current. Thus, a first electrode made of silver (Ag) having a thickness of 8 nm was formed at a deposition rate of 0.1 to 0.2 nm/second.

Here the aforesaid nitrogen containing compound employed is a compound indicated below.

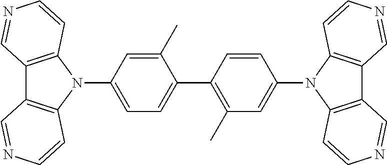 [SMILES: Cc1cc(-n2c3ccncc3c3cnccc32)ccc1-c1ccc(-n2c3ccncc3c3cnccc32)cc1C]

The substrate which was prepared to the first electrode was fixed to a substrate holder of the vacuum deposition apparatus available on the market. Then, after reducing the pressure of the vacuum tank to 4×10⁻⁴ Pa, a compound HT-1 was vapor deposited onto the substrate at a deposition rate of 0.1 nm/second, while transporting the substrate, whereby it was produced a hole transport layer (HTL) having a thickness of 20 nm.

Subsequently, there were vapor deposited a compound A-3 (blue light emitting dopant), a compound A-1 (green light emitting dopant), a compound A-2 (red light emitting dopant), and a compound H-1 (host compound) in such a manner that the content of the compound A-3 was linearly varied from 35 mass % to 5 mass % in the thickness direction by changing the deposition rate depending on the place; the compound A-1 and the compound A-2 were formed regardless of the thickness to have the content of 0.2 mass % at a deposition rate of 0.0002 nm/sec; and the compound H-1 was varied from 64.6 mass % to 94.6 mass % by changing the deposition rate depending on the place, whereby a light emitting layer having a thickness of 70 nm was formed with co-deposition.

Further, a compound ET-1 was vapor deposited to form an electron transport layer having a thickness of 30 nm. Subsequently, 2 nm thick potassium fluoride (KF) was vapor deposited. Moreover, aluminum was vapor deposited with a thickness of 100 nm to form a second electrode.

Here the aforesaid compound HT-1, compounds A-1, A-2 and A-3, compound H-1 and compound ET-1 are compounds indicated below.

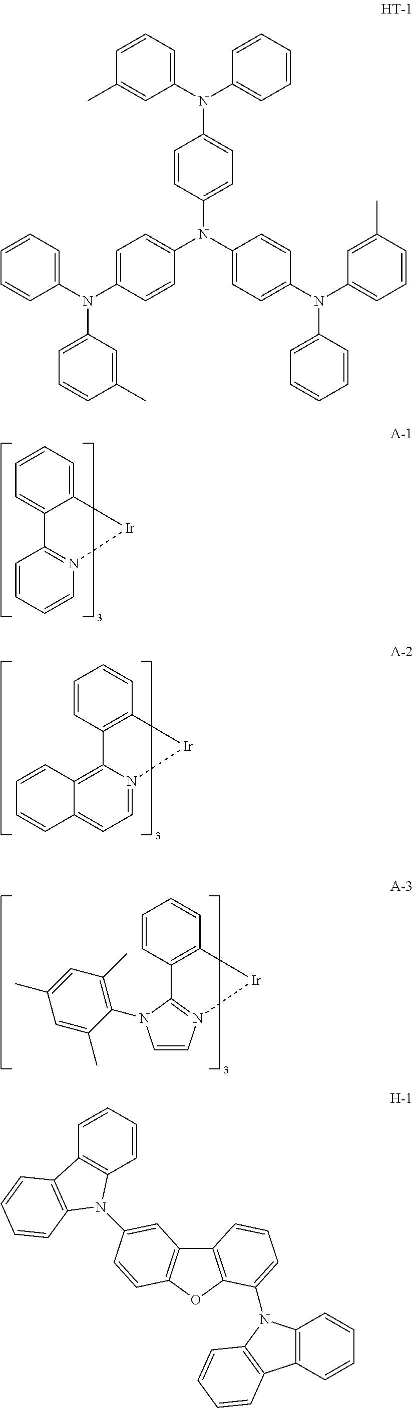

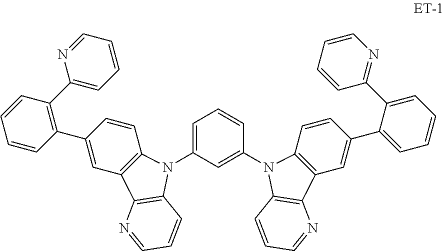 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

### [Formation of Covering Layer]

A covering layer was formed under any one of the following conditions c1 to c6.

The covering layer was formed in a manner of spreading over the light emitting unit layer which was disposed on the second gas barrier layer. The covering layer and the second gas barrier layer cover the whole light emitting unit layer.

### (Film Forming Condition c1)

The sample having been formed to the second electrode was transferred a CVD apparatus. Subsequently, after reducing the pressure of the vacuum tank of the CVD apparatus to 4×10⁻⁴ Pa, there were introduced a silane gas (SiH₄), an ammonia gas (NH₃), a nitrogen gas (N₂), and a hydrogen gas (H₂). By this, a silicon nitride film having a thickness of 300 nm was formed with a plasma CVD method. Thereby a covering layer was formed.

### (Film Forming Condition c2)

A covering layer was formed with the same method as the film forming condition al of the first gas barrier layer.

### (Film Forming Condition c3)

A covering layer was formed with the same method as the film forming condition a2 of the first gas barrier layer.

### (Film Forming Condition c4)

A covering layer was formed with the same method as the film forming condition c1 except that a thickness of a silicon nitride film formed with a plasma CVD method was made to be 500 nm.

### (Film Forming Condition c5)

A substrate was set in a vacuum tank of a sputtering apparatus. Then the vacuum tank evacuated to be an order of 10⁻⁴ Pa. After heating the inner temperature of the vacuum tank to 150° C., argon was introduced with a partial pressure of 0.1 Pa as a discharge gas. And oxygen was introduced with a partial pressure of 0.008 Pa as a reactive gas. After confirming stabilization of the atmospheric condition and the temperature, discharge was started with a sputtering power of 2 W/cm². Plasma was generated on the Si target, and a sputtering process was started. After stabilization of the process, a shutter was opened, and formation of a covering layer was started. When the layer thickness achieved 300 nm, the shutter was closed and the film forming process was terminated.

### (Film Forming Condition c6)

A covering layer was formed with the same method as the film forming condition c5 except that a thickness of the formed film was made to be 500 nm.

### [Sealing Adhesive Layer and Sealing Member]

Subsequently, an aluminum foil (thickness of 100 μm) laminated with a polyethylene terephthalate (PET) resin was used as a sealing member. On the aluminum side of this sealing member was coated with a heat curing liquid adhesive (an epoxy resin) with a thickness of 20 μm as a sealing layer. Then, this pasted sealing member was superposed on the substrate having been prepared to the second electrode. At this moment, the adhesive forming surface of the sealing member and the organic functional layer surface were continuously superposed in a manner that the edge portions of the taking out electrodes of the first electrode and the second electrode were made outside.

Then, the sample was placed in a reduced pressure apparatus, and the superposed substrate and the sealing member were pressed at 90° C. with 0.1 MPa and they were kept together for 5 minutes.

Subsequently, the sample was returned to an atmospheric pressure environment, followed by heated at 110° C. for 30 minutes to cure the adhesive. The above-described sealing process was done at an atmospheric pressure with a nitrogen environment having a water content of 1 ppm or less, with a measured cleanness of class 100, which was conformed with JIS B 9920, with a dew point of −80° C. or less, and oxygen concentration of 0.8 ppm or less.

In addition, the formation process of the taking out wirings of the first electrode and the second electrode were omitted in this description.

### [Third Gas Barrier Layer]

An organic EL element according to the present invention may be provided with a third gas barrier layer between the flexible substrate and the first gas barrier layer. The third gas barrier layer was formed with the following method.

In addition, when the third gas barrier layer was prepared, the first gas barrier layer was formed on the third gas barrier layer in the production of an organic EL element.

The third gas barrier layer was formed with a roll-to-roll CVD film forming apparatus, which is described in Japan Patent No. 4268195, and being a two linked type apparatus each having a film forming portion composed of opposing film forming rollers (containing a first film forming portion and a second film forming portion).

The film forming conditions were adjusted with the items of: transport rate (7 m/min), supplying amount of raw material (HMDSO) (150 sccm), supplying amount of oxygen (500 sccm), vacuum level (1.5 Pa), impressed electric power (4.5 kW), and frequency of electric source (90 kHz). A number of film forming process (repeated number of film forming process) was set to be three times. The film thickness was determined with a cross-section TEM.

### <<Production of Organic EL Elements 101 to 127>>

In accordance with the above-described production method of an organic EL element, organic EL elements 101 to 127 were produced having a first gas barrier layer, a second gas barrier layer, a covering layer, and a third gas barrier layer. These layers were prepared by the following conditions described in Table 2.

TABLE 2

| | First gas barrier | | Second gas barrier | | Covering | | Third gas barrier | | Hard | | |
|---|---|---|---|---|---|---|---|---|---|---|---|
| Organic | layer | | layer | | layer | | layer | | layer | | |
| EL | Film | Layer | Film | Layer | Film | Layer | Absence | Layer | Absence | Layer | |
| element | forming | thickness | forming | thickness | forming | thickness | or | thickness | or | thickness | |
| No. | condition | (nm) | condition | (nm) | condition | (nm) | Presence | (nm) | Presence | (nm) | Remarks |
| 101 | a1 | 250 | b1 | 15 | c1 | 300 | — | — | — | — | Inventive Example |
| 102 | a1 | 250 | b2 | 15 | c1 | 300 | — | — | — | — | Inventive Example |
| 103 | a1 | 250 | b3 | 15 | c1 | 300 | — | — | — | — | Inventive Example |
| 104 | a1 | 250 | b4 | 15 | c1 | 300 | — | — | — | — | Inventive Example |
| 105 | a1 | 250 | b5 | 15 | c1 | 300 | — | — | — | — | Inventive Example |
| 106 | a1 | 250 | b6 | 15 | c1 | 300 | — | — | — | — | Inventive Example |
| 107 | a1 | 250 | b7 | 15 | c1 | 300 | — | — | — | — | Inventive Example |
| 108 | a1 | 250 | b8 | 15 | c1 | 300 | — | — | — | — | Inventive Example |
| 109 | a1 | 250 | b9 | 15 | c1 | 300 | — | — | — | — | Inventive Example |
| 110 | a1 | 250 | b10 | 15 | c1 | 300 | — | — | — | — | Inventive Example |
| 111 | a1 | 250 | b11 | 15 | c1 | 300 | — | — | — | — | Inventive Example |
| 112 | a1 | 250 | b12 | 15 | c1 | 300 | — | — | — | — | inventive Example |
| 113 | a1 | 250 | b12 | 15 | c2 | 250 | — | — | — | — | Inventive Example |
| 114 | a1 | 250 | b12 | 15 | c3 | 500 | — | — | — | — | Inventive Example |
| 115 | a1 | 250 | b13 | 30 | c1 | 300 | — | — | — | — | Inventive Example |
| 116 | a1 | 250 | b14 | 5 | c1 | 300 | — | — | — | — | Inventive Example |
| 117 | a1 | 250 | b12 | 15 | c4 | 500 | — | — | — | — | Inventive Example |
| 118 | a1 | 250 | b12 | 15 | c5 | 300 | — | — | — | — | Inventive Example |
| 119 | a1 | 250 | b12 | 15 | c6 | 500 | — | — | — | — | Inventive Example |
| 120 | a2 | 500 | b12 | 15 | c4 | 500 | — | — | — | — | Inventive Example |
| 121 | a1 | 250 | b12 | 15 | c1 | 300 | Presence | 300 | — | — | Inventive Example |
| 122 | a2 | 500 | b12 | 15 | c4 | 500 | Presence | 300 | — | — | Inventive Example |
| 123 | a1 | 250 | — | — | — | — | — | — | — | — | Comparative Example |
| 124 | a1 | 250 | — | — | c1 | 300 | — | — | — | — | Comparative Example |
| 125 | a1 | 250 | — | — | c1 | 300 | — | — | Presence | 500 | Comparative Example |
| 126 | a1 | 250 | — | — | c4 | 500 | — | — | Presence | 500 | Comparative Example |
| 127 | a1 | 250 | — | — | c6 | 500 | — | — | Presence | 500 | Comparative Example |

Here, in the organic EL elements 125 to 127, a hard layer formed by curing the organic layer described below was used instead of the second gas barrier layer.

### [Hard Layer]

A mixture made of: 2-hydroxy-3-phenoxypropyl acrylate/propoxylated neopentylglycol diacrylate/ethoxylated trimethylolpropane triacrylate (mixed ratio=60/30/10) was used. An organic layer composed of the mixture was coated on the first gas barrier layer. An electron beam was irradiated to the formed organic layer to cure. Thus, a hard layer was formed. The layer thickness of the cured organic layer was adjusted to be 500 nm.

### <<Evaluation of Bending Resistance>>

A prepared organic EL element sample was curled around a cylinder having a radius of curvature of 7.5 mm (Condition 1), or a cylinder having a radius of curvature of 15 mm (Condition 2) in a manner that the flexible substrate of the organic EL element was bent in a convex direction. The sample was kept in this state for one second. Subsequently, for the purpose of bending the sample in the opposite direction, the sample was curled around the cylinder in a manner that the flexible substrate of the organic EL element was bent in a concave direction. The sample was kept in this state for one second. The bending operation of the organic EL element described above was called as “one cycle”. 100 cycles of this operation were repeated. The external appearance of the organic EL element after being subjected to 100 cycles of the operation was observed.

An evaluation of the bending resistance was done based on the following criteria in the case of employing a cylinder having a radius of 7.5 mm (Condition 1), and in the case of employing a cylinder having a radius of 15 mm (Condition 2).

1: Not observed a change of the external appearance of the organic EL element under both Condition 1 and Condition 2

2: Not observed a change of the external appearance of the organic EL element under Condition 2, however, observed a peel-off of the organic EL element under Condition 1

3: Observed a peel-off of the organic EL element under both Condition 1 and Condition 2

The above-described criteria 1 and 2 were decided to pass the examination in which it was not observed a change of the external appearance of the organic EL element under Condition 1 or Condition 2.

### [Evaluation of Storage Stability Under High Temperature and High Humidity Conditions]

A prepared organic EL element sample was curled around a cylinder having a radius of curvature of 10 mm in a manner that the flexible substrate of the organic EL element was bent in a convex direction. While keeping this condition, the sample was left at 60° C. and 90% RH for 500 hours. Then, the organic EL element sample was lighted with a constant voltage electric source. It was detected a width of a portion in which emission was not observed (a non-light emitting portion width). This width was evaluated based on the emission edge of an initial condition (in mm unit).

In order to keep the emission appearance, the non-light emitting portion width is preferably less than 2 mm. The organic EL element sample having the non-light emitting portion width is preferably less than 2 mm was decided to pass the examination.

### [Evaluation of Light Emitting Efficiency]

Light emitting efficiency was evaluated by measuring an external quantum efficiency (EQE) value. The luminance and the light emitting spectrum were measured with a Spectroradiometer CS-1000 (produced by Konica Minolta, Inc.). EQE was calculated with a luminance conversion method based on these measurement values. Here, EQE was indicated as a relative value by setting the EQE value of “Organic EL element 123” to be 100%.

The organic EL elements 101 to 127 were evaluated by using the above-described evaluation methods. The evaluation results are indicated in Table 3

TABLE 3

| | | Evaluation of | | |
|---|---|---|---|---|
| | | storage property | | |
| | | under high temperature | Evaluation of | |
| Organic | Evaluation | and high humidity | emission efficiency | |
| EL | of | conditions | (Relative value (%) of | |
| element | bending | (width of non-light | External quantum | |
| No. | resistance | emitting portion (nm)) | efficiency) | Remarks |
| 101 | 2 | 0.9 | 100 | Inventive Example |
| 102 | 1 | 0.6 | 116 | Inventive Example |
| 103 | 2 | 1.3 | 100 | Inventive Example |
| 104 | 2 | 1.9 | 103 | Inventive Example |
| 105 | 2 | 1.3 | 106 | Inventive Example |
| 106 | 2 | 2.0 | 103 | Inventive Example |
| 107 | 2 | 1.5 | 94 | Inventive Example |
| 108 | 2 | 1.1 | 97 | Inventive Example |
| 109 | 1 | 1.4 | 97 | Inventive Example |
| 110 | 1 | 1.3 | 100 | Inventive Example |
| 111 | 1 | Less than 0.1 | 116 | Inventive Example |
| 112 | 1 | Less than 0.1 | 129 | Inventive Example |
| 113 | 2 | 1.4 | 129 | inventive Example |
| 114 | 2 | 1.0 | 129 | Inventive Example |
| 115 | 1 | Less than 0.1 | 123 | Inventive Example |
| 116 | 1 | Less than 0.1 | 126 | Inventive Example |
| 117 | 1 | Less than 0.1 | 129 | Inventive Example |
| 118 | 1 | 0.5 | 129 | Inventive Example |
| 119 | 1 | 0.2 | 129 | Inventive Example |
| 120 | 1 | Less than 0.1 | 129 | Inventive Example |
| 121 | 1 | Less than 0.1 | 129 | Inventive Example |
| 122 | 1 | Less than 0.1 | 116 | Inventive Example |
| 123 | 1 | 9.3 | 100 | Comparative Example |
| 124 | 3 | Cannot be evaluated | 100 | Comparative Example |
| | | (Peel-off) | | |
| 125 | 2 | 2.9 | 94 | Comparative Example |
| 126 | 3 | Cannot be evaluated | 94 | Comparative Example |
| | | (Peel-off) | | |
| 127 | 2 | 2.2 | 94 | Comparative Example |

### <<Evaluation Results>>

As indicated by the results in Table 3, an organic EL element relating to the present invention was found to have an excellent bending resistance property without peeling off the element during bending compared with the comparative organic EL element. While keeping high bending resistance property, the organic EL element of the present invention may prevent generation of a non-light emitting portion when it is stored under high temperature and high humidity such as 60° C. and 90% RH. It has excellent sealing property. Further, it exhibits excellent emission efficiency.

### INDUSTRIAL APPLICABILITY

As described above, the present invention is suitable to provide an organic EL element having an excellent bending resistance property without peeling off the element during bending. The present invention is suitable to provide an organic EL element having a high sealing property which enables to prevent generation of a non-light emitting portion when it is stored under high temperature and high humidity while achieving high bending resistance property.

### DESCRIPTION OF SYMBOLS

100 and 200: Organic EL element (Organic electroluminescent element)
11: Flexible substrate (Substrate)
12: First gas barrier layer
13: Second gas barrier layer
14: First electrode
15: Organic functional layer
16: Second electrode
17: Light emitting unit layer
19: Sealing adhesive layer
20: Sealing member
21: Third gas barrier layer

1. An organic electroluminescent element comprising: a first gas barrier layer laminated on a substrate; a second gas barrier layer laminated on the first gas barrier layer; a light emitting unit layer laminated on the second gas barrier layer; and a covering layer spreading over the light emitting unit layer,
wherein the first gas barrier layer is a polysilazane reforming layer; and
the second gas barrier layer is a layer incorporating a metal oxide containing a metal element selected from the group consisting of: vanadium (V), niobium (Nb), tantalum (Ta), titanium (Ti), zirconium (Zr), hafnium (Hf), magnesium (Mg), yttrium (Y), and aluminum (Al).

2. The organic electroluminescent element of claim 1,
wherein a composition coefficient of an oxygen element contained in the metal oxide is smaller than a stoichiometric value.

3. The organic electroluminescent element of claim 1,
wherein the metal oxide contains niobium (Nb).

4. The organic electroluminescent element of claim 1,
wherein the covering layer contains silicon (Si) and nitrogen (N).

5. The organic electroluminescent element of claim 1,
wherein a third gas barrier layer is provided between the substrate and the first gas barrier layer; and
the third gas barrier layer incorporates a silicon compound containing an element selected from the group consisting of: carbon (C), nitrogen (N), and oxygen (O).
